(19) United States
(12) Patent Application Publication
(10) Pub. No.: US 2022/0190798 A1
(43) Pub. Date: Jun. 16, 2022

(54) JOSEPHSON TRAVELING WAVE PARAMETRIC AMPLIFIER DEVICE WITH SIDEBAND SUPPRESSION

(71) Applicant: International Business Machines Corporation, Armonk, NY (US)

(72) Inventors: Corrado P Mancini, Peekskill, NY (US); David Lokken-Toyli, White Plains, NY (US)

(21) Appl. No.: 17/118,058

(22) Filed: Dec. 10, 2020

(51) Int. Cl. H03F 19/00

(52) U.S. Cl. CPC H03F 19/00

(57) ABSTRACT

Devices and/or computer-implemented methods to facilitate a Josephson traveling wave parametric amplifier (JTWPA) device with sideband suppression are provided. According to an embodiment, a device can comprise a plurality of unit cells including at least one Josephson junction and a shunt capacitor. The device can further comprise a plurality of first dispersion resonators coupled to the plurality of unit cells at a first interval. The plurality of first dispersion resonators suppress generation of at least one of a third order harmonic of a pump tone applied to the device, a third order intermodulation product, or a fifth order intermodulation product.

### BACKGROUND

The subject disclosure relates to a Josephson traveling wave parametric amplifier (JTWPA) device, and more specifically, to a JTWPA device with sideband suppression.

Quantum computing is generally the use of quantum-mechanical phenomena for the purpose of performing computing and information processing functions. Quantum computing can be viewed in contrast to classical computing, which generally operates on binary values with transistors. That is, while classical computers can operate on bit values that are either 0 or 1, quantum computers operate on quantum bits (qubits) that comprise superpositions of both 0 and 1, can entangle multiple quantum bits, and use interference.

JTWPA devices are quantum limited amplifiers made up of a metamaterial transmission line of a long chain of Josephson junctions. Resonant phase-matching (RPM) in a JTWPA device uses the dispersion from loosely coupled hanger resonators (e.g., dispersion resonators) to enable efficient four-wave mixing for optimal gain performance. Quantum efficiency is used to describe the signal-to-noise ratio (SNR) performance of quantum limited amplification by a JTWPA device. A JTWPA device's quantum efficiency is the product of two internal efficiencies, one of which is set by relative ratio of gain and loss along the length of the device and the other is set by the noise contributions from the generation of undesired intermodulation products.

A problem with existing JTWPA devices is that the quantum efficiency of such devices is reduced by generation of undesired intermodulation products which limits qubit readout fidelity and quantum volume. Another problem with existing JTWPA devices is that they do not suppress unintended sidebands that occur out-of-band and lead to device instabilities and oscillations. Another problem with existing JTWPA devices is that they involve a non-negligible chip area (e.g., approximately 3 squared millimeters (mm²) to approximately 10 mm²). Thus, existing JTWPA devices are not suitable for use in quantum systems that will comprise a large number of qubits (e.g., 1,000 qubits or more) and many JTWPA devices whose total area will be a significant portion of a dilution refrigerator when considering their packaging and shielding.

### SUMMARY

The following presents a summary to provide a basic understanding of one or more embodiments of the invention. This summary is not intended to identify key or critical elements, or delineate any scope of the particular embodiments or any scope of the claims. Its sole purpose is to present concepts in a simplified form as a prelude to the more detailed description that is presented later. In one or more embodiments described herein, systems, devices, computer-implemented methods, and/or computer program products that facilitate a Josephson traveling wave parametric amplifier device with sideband suppression are described.

According to an embodiment, a device can comprise a plurality of unit cells including at least one Josephson junction and a shunt capacitor. The device can further comprise a plurality of first dispersion resonators coupled to the plurality of unit cells at a first interval. The plurality of first dispersion resonators suppress generation of at least one of a third order harmonic of a pump tone applied to the device, a third order intermodulation product, or a fifth order intermodulation product. An advantage of such a device is that it can provide sideband suppression to improve at least one of quantum efficiency, gain per unit length, stability, or noise performance of the device.

In some embodiments, the plurality of first dispersion resonators operate at defined operating frequencies to create a stopband that increases dispersion and attenuates at least one of the third order harmonic of the pump tone, the third order intermodulation product, or the fifth order intermodulation product. The plurality of first dispersion resonators operate at the defined operating frequencies to improve at least one of: quantum efficiency, gain per unit length, stability, or noise performance of the device. An advantage of such a device is that it can provide sideband suppression to improve at least one of quantum efficiency, gain per unit length, stability, or noise performance of the device.

According to another embodiment, a computer-implemented method can comprise applying, by a system operatively coupled to a processor, a pump tone to a Josephson traveling wave parametric amplifier device comprising a plurality of unit cells having at least one Josephson junction and a shunt capacitor. The computer-implemented method can further comprise suppressing, by the system, generation of at least one of a third order harmonic of the pump tone, a third order intermodulation product, or a fifth order intermodulation product using a plurality of first dispersion resonators coupled to the plurality of unit cells at a first interval. An advantage of such computer-implemented method is that it can be implemented to provide the Josephson traveling wave parametric amplifier device with sideband suppression to improve at least one of quantum efficiency, gain per unit length, stability, or noise performance of the Josephson traveling wave parametric amplifier device.

In some embodiments, the computer-implemented method can further comprise operating, by the system, the plurality of first dispersion resonators at defined operating frequencies to create a stopband that increases dispersion and attenuates at least one of the third order harmonic of the pump tone, the third order intermodulation product, or the fifth order intermodulation product and to improve at least one of: quantum efficiency, gain per unit length, stability, or noise performance of the Josephson traveling wave parametric amplifier device. An advantage of such computer-implemented method is that it can be implemented to provide the Josephson traveling wave parametric amplifier device with sideband suppression to improve at least one of quantum efficiency, gain per unit length, stability, or noise performance of the Josephson traveling wave parametric amplifier device.

According to an embodiment, a device can comprise a plurality of unit cells including at least one Josephson junction and a shunt capacitor. The device can further comprise a plurality of first dispersion resonators coupled to the plurality of unit cells at a first interval and operative to generate sideband suppression. An advantage of such a device is that it can provide sideband suppression to improve at least one of quantum efficiency, gain per unit length, stability, or noise performance of the device.

In some embodiments, the plurality of first dispersion resonators operate at defined operating frequencies to create a stopband that increases dispersion and attenuates at least one of a third order harmonic of a pump tone applied to the device, a third order intermodulation product, or a fifth order intermodulation product. The plurality of first dispersion resonators operate at the defined operating frequencies to improve at least one of: quantum efficiency, gain per unit length, stability, or noise performance of the device. An advantage of such a device is that it can provide sideband suppression to improve at least one of quantum efficiency, gain per unit length, stability, or noise performance of the device.

According to another embodiment, a computer-implemented method can comprise applying, by a system operatively coupled to a processor, a pump tone to a Josephson traveling wave parametric amplifier device comprising a plurality of unit cells having at least one Josephson junction and a shunt capacitor. The computer-implemented method can further comprise generating, by the system, sideband suppression using a plurality of first dispersion resonators coupled to the plurality of unit cells at a first interval. An advantage of such computer-implemented method is that it can be implemented to provide the Josephson traveling wave parametric amplifier device with sideband suppression to improve at least one of quantum efficiency, gain per unit length, stability, or noise performance of the Josephson traveling wave parametric amplifier device.

In some embodiments, the computer-implemented method can further comprise operating, by the system, the plurality of first dispersion resonators at defined operating frequencies to create a stopband that increases dispersion and attenuates at least one of a third order harmonic of a pump tone applied to the Josephson traveling wave parametric amplifier device, a third order intermodulation product, or a fifth order intermodulation product and to improve at least one of: quantum efficiency, gain per unit length, stability, or noise performance of the Josephson traveling wave parametric amplifier device. An advantage of such computer-implemented method is that it can be implemented to provide the Josephson traveling wave parametric amplifier device with sideband suppression to improve at least one of quantum efficiency, gain per unit length, stability, or noise performance of the Josephson traveling wave parametric amplifier device.

According to an embodiment, a device can comprise a first dispersion resonator coupled to a first unit cell of a Josephson traveling wave parametric amplifier device and that generates sideband suppression. The device can further comprise a second dispersion resonator coupled to a second unit cell of the Josephson traveling wave parametric amplifier device and that amplifies a quantum signal. An advantage of such a device is that it can provide sideband suppression to improve at least one of quantum efficiency, gain per unit length, stability, or noise performance of the Josephson traveling wave parametric amplifier device.

In some embodiments, the first dispersion resonator operates at a defined operating frequency to create a stopband that increases dispersion and attenuates at least one of a third order harmonic of a pump tone applied to the Josephson traveling wave parametric amplifier device, a third order intermodulation product, or a fifth order intermodulation product. The first dispersion resonator operates at the defined operating frequency to improve at least one of: quantum efficiency, gain per unit length, stability, or noise performance of the Josephson traveling wave parametric amplifier device. An advantage of such a device is that it can provide sideband suppression to improve at least one of quantum efficiency, gain per unit length, stability, or noise performance of the Josephson traveling wave parametric amplifier device.

### DESCRIPTION OF THE DRAWINGS

FIGS. 1 and 2 illustrate circuit diagrams of example, non-limiting devices that can facilitate a JTWPA device with sideband suppression in accordance with one or more embodiments described herein.

FIG. 3 illustrates an example, non-limiting graph that can facilitate a JTWPA device with sideband suppression in accordance with one or more embodiments described herein.

FIG. 4 illustrates an example, non-limiting graph that can facilitate a JTWPA device with sideband suppression in accordance with one or more embodiments described herein.

FIG. 5 illustrates an example, non-limiting graph that can facilitate a JTWPA device with sideband suppression in accordance with one or more embodiments described herein.

FIGS. 6, 7, 8, and 9 illustrate flow diagrams of example, non-limiting computer-implemented methods that can facilitate a JTWPA device with sideband suppression in accordance with one or more embodiments described herein.

FIG. 10 illustrates a block diagram of an example, non-limiting operating environment in which one or more embodiments described herein can be facilitated.

### DETAILED DESCRIPTION

The following detailed description is merely illustrative and is not intended to limit embodiments and/or application or uses of embodiments. Furthermore, there is no intention to be bound by any expressed or implied information presented in the preceding Background or Summary sections, or in the Detailed Description section.

One or more embodiments are now described with reference to the drawings, where like referenced numerals are used to refer to like elements throughout. In the following description, for purposes of explanation, numerous specific details are set forth in order to provide a more thorough understanding of the one or more embodiments. It is evident, however, in various cases, that the one or more embodiments can be practiced without these specific details.

Given the problems described above with existing JTWPA devices, the present disclosure can be implemented to produce a solution to these problems in the form of devices and/or computer-implemented methods that can facilitate JTWPA devices with sideband suppression by using a device comprising: a plurality of unit cells including at least one Josephson junction and a shunt capacitor; and a plurality of first dispersion resonators coupled to the plurality of unit cells at a first interval, where the plurality of first dispersion resonators suppress generation of at least one of a third order harmonic of a pump tone applied to the device, a third order intermodulation product, or a fifth order intermodulation product. An advantage of such devices and/or computer-implemented methods is that they can be implemented to provide the device with sideband suppression to improve at least one of quantum efficiency, gain per unit length, stability, or noise performance of the device.

In some embodiments, the present disclosure can be implemented to produce a solution to the problems described above in the form of devices and/or computer-implemented methods that can facilitate JTWPA devices with sideband suppression by using the above described device, where the plurality of first dispersion resonators operate at defined operating frequencies to create a stopband that increases dispersion and attenuates at least one of the third order harmonic of the pump tone, the third order intermodulation product, or the fifth order intermodulation product, and where the plurality of first dispersion resonators operate at the defined operating frequencies to improve at least one of: quantum efficiency, gain per unit length, stability, or noise performance of the device. An advantage of such devices and/or computer-implemented methods is that they can be implemented to provide the device with sideband suppression to improve at least one of quantum efficiency, gain per unit length, stability, or noise performance of the device.

It will be understood that when an element is referred to as being “coupled” to another element, it can describe one or more different types of coupling including, but not limited to, capacitive coupling, chemical coupling, communicative coupling, electrical coupling, electromagnetic coupling, inductive coupling, operative coupling, optical coupling, physical coupling, thermal coupling, and/or another type of coupling. As referenced herein, an “entity” can comprise a human, a client, a user, a computing device, a software application, an agent, a machine learning model, an artificial intelligence, and/or another entity. It should be appreciated that such an “entity” can facilitate the design, fabrication, and/or implementation (e.g., simulation, quantizing, and/or testing) of one or more embodiments of the subject disclosure described herein.

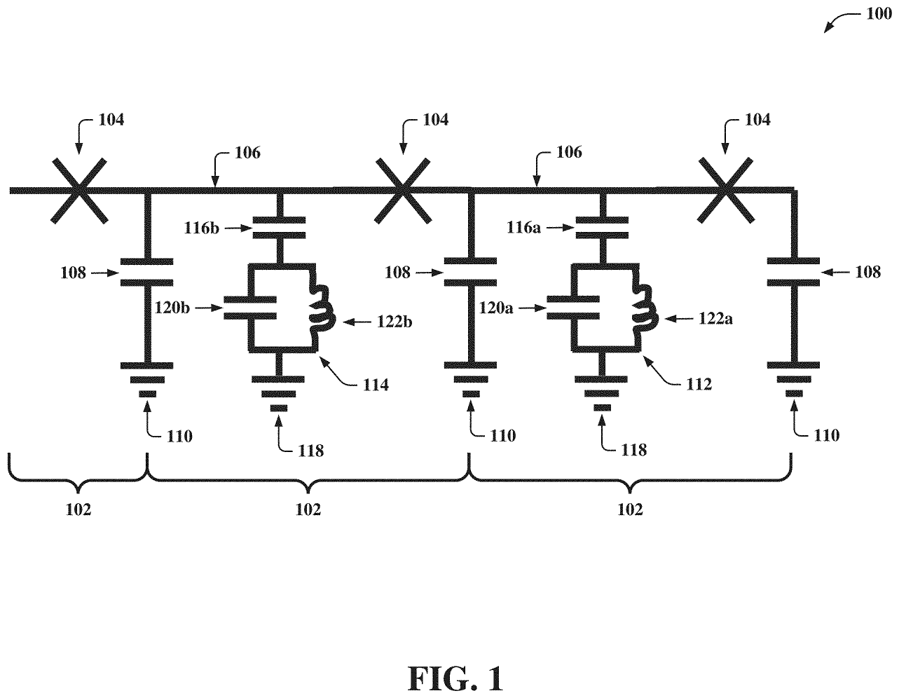

FIG. 1 illustrates a circuit diagram of an example, non-limiting device 100 that can facilitate a JTWPA device with sideband suppression in accordance with one or more embodiments described herein. Device 100 can comprise a semiconducting and/or a superconducting device that can be implemented in a quantum device. For example, device 100 can comprise an integrated semiconducting and/or superconducting circuit (e.g., a quantum circuit) that can be implemented in a quantum device such as, for instance, quantum hardware, a quantum processor, a quantum computer, and/or another quantum device. Device 100 can comprise a semiconducting and/or a superconducting device such as, for instance, a JTWPA device with sideband suppression that can be implemented in such a quantum device defined above. For example, device 100 can comprise a JTWPA device that can generate sideband suppression in accordance with one or more embodiments of the subject disclosure and can further be implemented in the above defined quantum device.

In some embodiments, device 100 can comprise a JTWPA device that can be integrated into a circuit (e.g., a quantum circuit or a superconducting circuit) and/or a processor (e.g., a quantum processor) by, for instance, using microwave interconnects including, but not limited to, wirebonds, bump bonds, mechanical interconnects (e.g., pogo pins), and/or another microwave interconnect. In these embodiments, such microwave interconnects can couple (e.g., connect) device 100 to wiring layers comprising, for instance, printed circuit boards, laminate boards, flexible wiring, and/or coaxial cables. In these embodiments, such wiring layers can couple (e.g., connect) device 100 to other microwave components such as, for example, directional couplers, attenuators, isolators, filters, amplifiers, and/or another microwave component. In some embodiments, device 100 can be directly co-fabricated on the same chip as a quantum processor or other microwave elements.

As illustrated in the example embodiment depicted in FIG. 1, device 100 can comprise a plurality of unit cells 102. In this example embodiment, each of such unit cells 102 can comprise at least one Josephson junction 104 provided on a transmission line 106, a shunt capacitor 108 coupled to transmission line 106, and a ground 110 coupled to shunt capacitor 108. As illustrated in the example embodiment depicted in FIG. 1, device 100 can further comprise a first dispersion resonator 112 and a second dispersion resonator 114 respectively coupled (e.g., capacitively coupled) to a unit cell 102 and transmission line 106 via a coupling capacitor 116a and 116b. In this example embodiment, first dispersion resonator 112 and second dispersion resonator 114 can also be respectively coupled to a ground 118. As illustrated in the example embodiment depicted in FIG. 1, first dispersion resonator 112 and second dispersion resonator 114 can respectively comprise a resonator capacitor 120a and 120b and a resonator inductor 122a and 122b.

In some embodiments, first dispersion resonator 112 and second dispersion resonator 114 can respectively comprise a lumped element resonator, a transmission line resonator, or another type of resonator. In various embodiments, shunt capacitor 108, coupling capacitor 116a, coupling capacitor 116b, resonator capacitor 120a, and/or resonator capacitor 120b can respectively comprise, for instance, a parallel plate capacitor, a planar capacitor (e.g., an interdigitated capacitor) through transmission line sections connecting Josephson junctions 104, and/or another capacitor. In various embodiments, one or more operating parameters (e.g., coupling capacitance, operating frequency, and/or another parameter) of coupling capacitor 116a, coupling capacitor 116b, resonator capacitor 120a, resonator capacitor 120b, resonator inductor 122a, and/or resonator inductor 122b can be the same or different. In these embodiments, the coupling capacitance of one or more of such components can be determined using, for instance, Equation (1), (2), (3), and/or (4) defined below, while the operating frequency of one or more of such components can be set during design and/or fabrication of device 100.

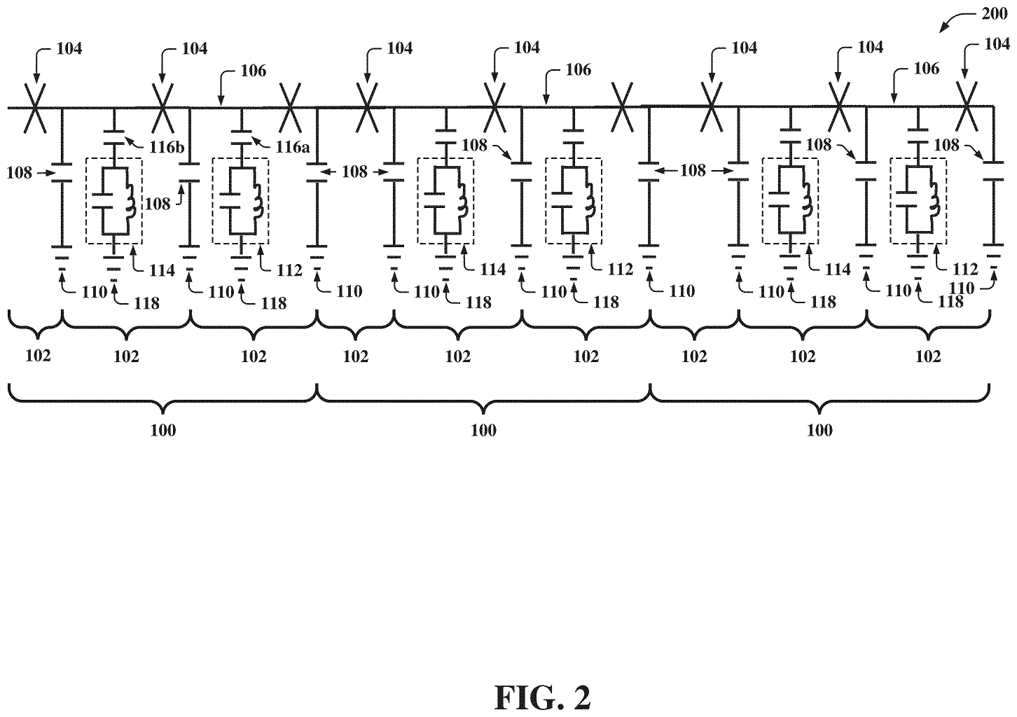

Although device 100 illustrates only three unit cells 102, one first dispersion resonator 112, and one second dispersion resonator 114, it should be appreciated that the subject disclosure is not so limiting. For example, in some embodiments, device 100 can comprise a plurality of unit cells 102, a plurality of first dispersion resonators 112, and/or a plurality of second dispersion resonators 114. For instance, as described below with reference to the example embodiment depicted in FIG. 2, device 200 can comprise a plurality of unit cells 102, a plurality of first dispersion resonators 112, and/or a plurality of second dispersion resonators 114.

In the example embodiment illustrated in FIG. 1, based on device 100 (e.g., transmission line 106) receiving a pump tone as described below, second dispersion resonator 114 can reduce phase-mismatch to provide a defined four-wave mixing operation (e.g., an optimized four-wave mixing operation) and/or amplification of a quantum signal and first dispersion resonator 112 can generate sideband suppression. To receive such a pump tone, device 100, first dispersion resonator 112, and/or second dispersion resonator 114 can be coupled to an external device (not illustrated in the figures). For example, device 100, first dispersion resonator 112, and/or second dispersion resonator 114 can be coupled (e.g., via transmission line 106) to an external device that can be external to device 100 such as, for instance, a pulse generator device and/or a microwave laser device.

In an example embodiment, although not depicted in FIG. 1, device 100, first dispersion resonator 112, and/or second dispersion resonator 114 can be coupled to a pulse generator device including, but not limited to, an arbitrary waveform generator (AWG), a vector network analyzer (VNA), and/or another pulse generator device that can be external to device 100 and can transmit and/or receive pulses (e.g., microwave pulses, microwave signals, control signals, and/or another pulse) to and/or from device 100, first dispersion resonator 112, and/or second dispersion resonator 114. In another example embodiment, although not depicted in FIG. 1, device 100, first dispersion resonator 112, and/or second dispersion resonator 114 can be coupled (e.g., via transmission line 106) to a microwave laser device including, but not limited to, a maser, and/or another microwave laser device that can be external to device 100 and can transmit and/or receive a laser of microwave light to and/or from device 100, first dispersion resonator 112, and/or second dispersion resonator 114.

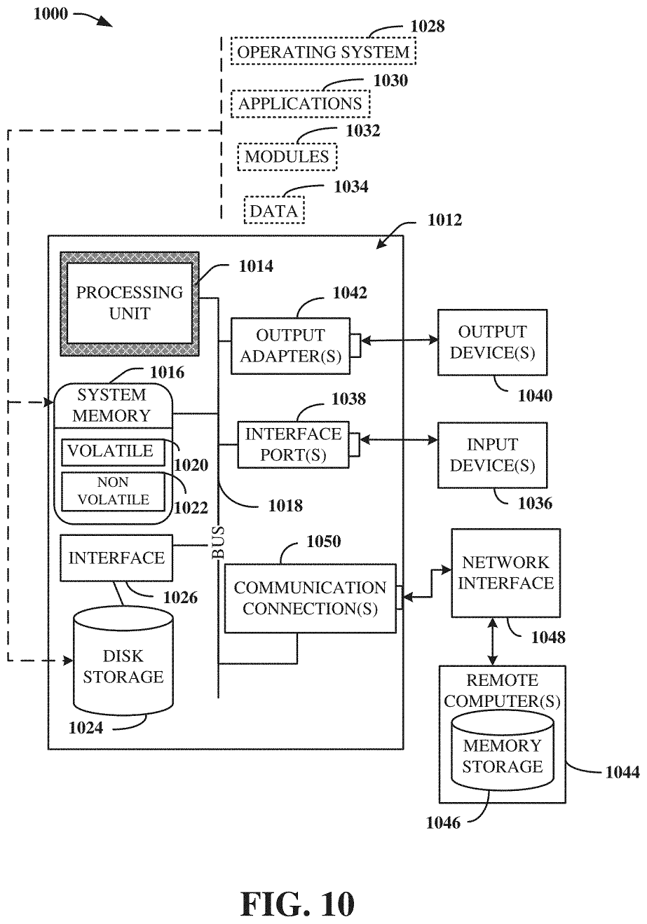

In accordance with one or more embodiments of the subject disclosure, such an external device described above (e.g., an AWG, a VNA, a maser, and/or another external device) can also be coupled to a computer comprising a memory that can store instructions thereon and a processor that can execute such instructions. For example, in these embodiments, such an external device described above (e.g., an AWG, a VNA, a maser, and/or another external device) can also be coupled to a computer 1012 described below with reference to FIG. 10, where computer 1012 can comprise a system memory 1016 that can store instructions thereon (e.g., software, routines, processing threads, and/or other instructions) and a processing unit 1014 that can execute such instructions. In these embodiments, such a computer can be employed to operate and/or control (e.g., via processing unit 1014 executing instructions stored on system memory 1016) such an external device described above (e.g., an AWG, a VNA, a maser, and/or another external device). For instance, in these embodiments, such a computer can be employed to enable the external device described above (e.g., an AWG, a VNA, a maser, and/or another external device) to: a) transmit and/or receive pulses (e.g., microwave pulses, microwave signals, control signals, and/or another pulse) to and/or from device 100, first dispersion resonator 112, and/or second dispersion resonator 114; and/or b) transmit and/or receive a laser of microwave light to and/or from device 100, first dispersion resonator 112, and/or second dispersion resonator 114.

In the embodiments described above, such pulses and/or laser of microwave light can constitute a pump tone that can be provided to, for instance, transmission line 106 of device 100. In these embodiments, based on device 100 (e.g., transmission line 106) receiving a pump tone as described above, second dispersion resonator 114 can reduce phase-mismatch to provide a defined four-wave mixing operation (e.g., an optimized four-wave mixing operation) and/or amplification of a quantum signal and first dispersion resonator 112 can generate sideband suppression.

In an embodiment, based on device 100 (e.g., transmission line 106) receiving a pump tone as described above, second dispersion resonator 114 can reduce phase-mismatch to provide a defined four-wave mixing operation (e.g., an optimized four-wave mixing operation) and/or amplification of a quantum signal by counteracting the dispersion of transmission line 106. In this embodiment, based on device 100 (e.g., transmission line 106) receiving a pump tone as described above, first dispersion resonator 112 can generate sideband suppression to suppress and/or suppress generation of a third order harmonic of the pump tone applied to device 100 (e.g., to transmission line 106), a third order intermodulation product, and/or a fifth order intermodulation product. In various embodiments: the third order harmonic of the pump tone applied to device 100 can be denoted as 3ωₚ, where ωₚ denotes pump angular frequency of the pump tone; the third order intermodulation product can be denoted as 2ωₚ+ωₛ, where ωₛ denotes signal angular frequency; and the fifth order intermodulation product can be denoted as 4ωₚ−ωₛ. The idler angular frequency can be denoted as ωᵢ, where wᵢ=2ωₚ−ωₛ.

To generate such sideband suppression, based on device 100 (e.g., transmission line 106) receiving a pump tone as described above, first dispersion resonator 112 can operate at a defined operating frequency (e.g., a defined resonant frequency) to create a stopband that increases dispersion and attenuates the third order harmonic of the pump tone applied to device 100, the third order intermodulation product, and/or the fifth order intermodulation product. For example, first dispersion resonator 112 can operate at a defined operating frequency ranging from approximately 1 gigahertz (GHz) to approximately 100 GHz to create such a stopband that increases dispersion and attenuates the third order harmonic of the pump tone applied to device 100, the third order intermodulation product, and/or the fifth order intermodulation product. In this example, such a stopband can increase dispersion to limit generation of the third order harmonic of the pump tone applied to device 100, the third order intermodulation product, and/or the fifth order intermodulation product.

In an example, to create the above described stopband, first dispersion resonator 112 can operate at a defined operating frequency that is approximately equal to, for instance, the third order harmonic of the pump tone applied to device 100, the third order intermodulation product, and/or the fifth order intermodulation product. In this example, the third order harmonic of the pump tone applied to device 100, the third order intermodulation product, and/or the fifth order intermodulation product constitute higher order sidebands that are sources of quantum noise that device 100 can reduce by limiting signal coupling to these modes. In this example, based on first dispersion resonator 112 operating at such a defined operating frequency to create such a stopband, device 100 and/or first dispersion resonator 112 can thereby improve at least one of: quantum efficiency, gain per unit length, stability, or noise performance of device 100. In various embodiments, such a defined operating frequency of first dispersion resonator 112 can be set during design and/or fabrication of device 100.

In an embodiment, based on device 100 (e.g., transmission line 106) receiving a pump tone as described above, second dispersion resonator 114 can minimize the phase-mismatch between the input signal, the pump tone, and an idler that is generated and first dispersion resonator 112 can maximize phase-mismatch corresponding to a four-wave mixing generation of a third order harmonic of the pump tone applied to device 100, a third order intermodulation product, and/or a fifth order intermodulation product. For example, the location of first dispersion resonator 112 and/or second dispersion resonator 114 on device 100 with respect to unit cells 102 can affect the respective coupling strength of first dispersion resonator 112 and/or second dispersion resonator 114 to transmission line 106. In the example embodiment depicted in FIG. 1, second dispersion resonator 114 can be positioned on device 100 such that when device 100 (e.g., transmission line 106) receives a pump tone as described above, second dispersion resonator 114 can minimize the phase-mismatch between the input signal, the pump tone, and an idler that is generated. In this example embodiment, first dispersion resonator 112 can be positioned on device 100 such that when device 100 (e.g., transmission line 106) receives a pump tone as described above, first dispersion resonator 112 can maximize phase-mismatch corresponding to a four-wave mixing generation of a third order harmonic of the pump tone applied to device 100, a third order intermodulation product, and/or a fifth order intermodulation product.

To determine desired coupling strengths of first dispersion resonator 112 and/or second dispersion resonator 114 and/or to determine the desired locations of such resonators on device 100 (e.g., where such locations are also referred to as the resonant phase-matching (RPM) periods), an entity as defined herein that implements device 100 can use phase-mismatch calculations. For example, such an entity can use Equations (1), (2), (3), and/or (4) defined below to perform such phase-mismatch calculations, to determine desired coupling strengths of first dispersion resonator 112 and/or second dispersion resonator 114, and/or to determine the desired locations of such resonators on device 100 (e.g., to determine the desired RPM periods of such resonators). For instance, such an entity can use Equation (1) defined below to minimize phase-mismatch corresponding to operation of second dispersion resonator 114 by minimizing |Δk|. In another example, such an entity can use Equations (2), (3), and (4) defined below to maximize phase-mismatch corresponding to operation of first dispersion resonator 112 by maximizing |Δk_{IM3}|, |Δk_{IM5}|, and |Δkₚ₃|.

Δk=2kₚ−kₛ−kᵢ (1)

where Δk denotes phase-mismatch, kₚ denotes pump wave vector, kₛ denotes signal wave vector, and kᵢ denotes idler wave vector.

Δk_{IM3}=2kₚ+kₛ−k_{IM3} (2)

where Δk_{IM3} denotes third order intermodulation product phase-mismatch and k_{IM3} denotes third order intermodulation product wave vector.

Δk_{IM5}=2kₚ+kᵢ−k_{IM5} (3)

where Δk_{IM5} denotes fifth order intermodulation product phase-mismatch and k_{IMs} denotes fifth order intermodulation product wave vector.

Δkₚ₃=3kₚ−kₚ₃ (4)

where Δkₚ₃ denotes third harmonic of the pump phase-mismatch and kₚ₃ denotes third harmonic of the pump wave vector.

Fabrication of device 100 can comprise multi-step sequences of, for example, photolithographic and/or chemical processing steps that facilitate gradual creation of electronic-based systems, devices, components, and/or circuits in a semiconducting and/or a superconducting device (e.g., an integrated circuit). For instance, device 100 can be fabricated on one or more substrates (e.g., a silicon (Si) substrates, and/or another substrate) by employing techniques including, but not limited to: photolithography, microlithography, nanolithography, nanoimprint lithography, photomasking techniques, patterning techniques, photoresist techniques (e.g., positive-tone photoresist, negative-tone photoresist, hybrid-tone photoresist, and/or another photoresist technique), etching techniques (e.g., reactive ion etching (RIE), dry etching, wet etching, ion beam etching, plasma etching, laser ablation, and/or another etching technique), evaporation techniques, sputtering techniques, plasma ashing techniques, thermal treatments (e.g., rapid thermal anneal, furnace anneals, thermal oxidation, and/or another thermal treatment), chemical vapor deposition (CVD), atomic layer deposition (ALD), physical vapor deposition (PVD), molecular beam epitaxy (MBE), electrochemical deposition (ECD), chemical-mechanical planarization (CMP), backgrinding techniques, and/or another technique for fabricating an integrated circuit.

Device 100 can be fabricated using various materials. For example, device 100 can be fabricated using materials of one or more different material classes including, but not limited to: conductive materials, semiconducting materials, superconducting materials, dielectric materials, polymer materials, organic materials, inorganic materials, non-conductive materials, and/or another material that can be utilized with one or more of the techniques described above for fabricating an integrated circuit.

FIG. 2 illustrates a circuit diagram of an example, non-limiting device 200 that can facilitate a JTWPA device with sideband suppression in accordance with one or more embodiments described herein. Repetitive description of like elements and/or processes employed in respective embodiments is omitted for sake of brevity.

Device 200 can comprise an example, non-limiting alternative embodiment of device 100 described above with reference to FIG. 1, where device 200 can comprise multiple devices 100 as illustrated in the example embodiment depicted in FIG. 2. Device 200 can comprise a semiconducting and/or a superconducting device that can be implemented in a quantum device. For example, device 200 can comprise an integrated semiconducting and/or superconducting circuit (e.g., a quantum circuit) that can be implemented in a quantum device such as, for instance, quantum hardware, a quantum processor, a quantum computer, and/or another quantum device. In some embodiments, device 200 can comprise a semiconducting and/or a superconducting device that can be implemented in a radio astronomy device and/or system, a dark matter detection device and/or system, and/or another precision measurement device and/or system that utilizes low temperature electronics. Device 200 can comprise a semiconducting and/or a superconducting device such as, for instance, a JTWPA device with sideband suppression that can be implemented in such a quantum device defined above. For example, device 200 can comprise a JTWPA device that can generate sideband suppression in accordance with one or more embodiments of the subject disclosure and can further be implemented in the above defined quantum device.

In some embodiments, device 200 can comprise a JTWPA device that can be integrated into a circuit (e.g., a quantum circuit or a superconducting circuit) and/or a processor (e.g., a quantum processor) by, for instance, using microwave interconnects including, but not limited to, wirebonds, bump bonds, mechanical interconnects (e.g., pogo pins), and/or another microwave interconnect. In these embodiments, such microwave interconnects can couple (e.g., connect) device 200 to wiring layers comprising, for instance, printed circuit boards, laminate boards, flexible wiring, and/or coaxial cables. In these embodiments, such wiring layers can couple (e.g., connect) device 200 to other microwave components such as, for example, directional couplers, attenuators, isolators, filters, amplifiers, and/or another microwave component. In some embodiments, device 200 can be directly co-fabricated on the same chip as a quantum processor or other microwave elements.

As illustrated in the example embodiment depicted in FIG. 2, device 200 can comprise a plurality of unit cells 102. In this example embodiment, each of such unit cells 102 can comprise at least one Josephson junction 104 provided on a transmission line 106, a shunt capacitor 108 coupled to transmission line 106, and a ground 110 coupled to shunt capacitor 108. As illustrated in the example embodiment depicted in FIG. 2, device 200 can further comprise a plurality of first dispersion resonators 112 and a plurality of second dispersion resonators 114 respectively coupled (e.g., capacitively coupled) to a unit cell 102 and transmission line 106 via a coupling capacitor 116a and 116b. For clarity, only one of each coupling capacitor 116a and 116b are annotated in the example embodiment depicted in FIG. 2. In this example embodiment, each first dispersion resonator 112 and each second dispersion resonator 114 can also be respectively coupled to a ground 118. Although not annotated in the example embodiment depicted in FIG. 2 for purposes of clarity, each first dispersion resonator 112 and each second dispersion resonator 114 can respectively comprise a resonator capacitor 120a and 120b and a resonator inductor 122a and 122b.

In some embodiments, each first dispersion resonator 112 and each second dispersion resonator 114 can respectively comprise a lumped element resonator, a transmission line resonator, or another type of resonator. In various embodiments, shunt capacitor 108, coupling capacitor 116a and 116b, and/or resonator capacitor 120a and 120b can respectively comprise, for instance, a parallel plate capacitor, a planar capacitor (e.g., an interdigitated capacitor) through transmission line sections connecting Josephson junctions 104, and/or another capacitor. In various embodiments, one or more operating parameters (e.g., coupling capacitance, operating frequency, and/or another parameter) of coupling capacitor 116a, coupling capacitor 116b, resonator capacitor 120a, resonator capacitor 120b, resonator inductor 122a, and/or resonator inductor 122b can be the same or different. In these embodiments, the coupling capacitance of one or more of such components can be determined using, for instance, Equation (1), (2), (3), and/or (4) defined below, while the operating frequency of one or more of such components can be set during design and/or fabrication of device 200.

In the example embodiment depicted in FIG. 2, first dispersion resonators 112 can be coupled to the plurality of unit cells 102 at a first interval. For example, first dispersion resonators 112 can be coupled to the plurality of unit cells 102 at a first interval constituting a first RPM period that can be defined as a certain number of unit cells 102 provided between each of the first dispersion resonators 112. In the example embodiment depicted in FIG. 2, second dispersion resonators 114 can be coupled to the plurality of unit cells 102 at a second interval. For example, second dispersion resonators 114 can be coupled to the plurality of unit cells 102 at a second interval constituting a second RPM period that can be defined as a certain number of unit cells 102 provided between each of the second dispersion resonators 114. In an embodiment, the above defined first interval (e.g., a first RPM period) and second interval (e.g., a second RPM period) can be the same. In another embodiment, the above defined first interval (e.g., a first RPM period) and second interval (e.g., a second RPM period) can be different. In the example embodiment illustrated in FIG. 2, first dispersion resonators 112 and second dispersion resonators 114 are each coupled to the plurality of unit cells 102 at an interval of three unit cells 102 (e.g., RPM period=3).

In the example embodiment illustrated in FIG. 2, based on device 200 (e.g., transmission line 106) receiving a pump tone as described below, second dispersion resonators 114 can reduce phase-mismatch to provide a defined four-wave mixing operation (e.g., an optimized four-wave mixing operation) and/or amplification of a quantum signal and first dispersion resonators 112 can generate sideband suppression. To receive such a pump tone, device 200, first dispersion resonators 112, and/or second dispersion resonators 114 can be coupled to an external device (not illustrated in the figures). For example, device 200, first dispersion resonators 112, and/or second dispersion resonators 114 can be coupled (e.g., via transmission line 106) to an external device that can be external to device 200 such as, for instance, a pulse generator device and/or a microwave laser device.

In an example embodiment, although not depicted in FIG. 2, device 200, first dispersion resonators 112, and/or second dispersion resonators 114 can be coupled to a pulse generator device including, but not limited to, an arbitrary waveform generator (AWG), a vector network analyzer (VNA), and/or another pulse generator device that can be external to device 200 and can transmit and/or receive pulses (e.g., microwave pulses, microwave signals, control signals, and/or another pulse) to and/or from device 200, first dispersion resonators 112, and/or second dispersion resonators 114. In another example embodiment, although not depicted in FIG. 2, device 200, first dispersion resonators 112, and/or second dispersion resonators 114 can be coupled (e.g., via transmission line 106) to a microwave laser device including, but not limited to, a maser, and/or another microwave laser device that can be external to device 200 and can transmit and/or receive a laser of microwave light to and/or from device 200, first dispersion resonators 112, and/or second dispersion resonators 114.

In accordance with one or more embodiments of the subject disclosure, such an external device described above (e.g., an AWG, a VNA, a maser, and/or another external device) can also be coupled to a computer comprising a memory that can store instructions thereon and a processor that can execute such instructions. For example, in these embodiments, such an external device described above (e.g., an AWG, a VNA, a maser, and/or another external device) can also be coupled to a computer 1012 described below with reference to FIG. 10, where computer 1012 can comprise a system memory 1016 that can store instructions thereon (e.g., software, routines, processing threads, and/or other instructions) and a processing unit 1014 that can execute such instructions. In these embodiments, such a computer can be employed to operate and/or control (e.g., via processing unit 1014 executing instructions stored on system memory 1016) such an external device described above (e.g., an AWG, a VNA, a maser, and/or another external device). For instance, in these embodiments, such a computer can be employed to enable the external device described above (e.g., an AWG, a VNA, a maser, and/or another external device) to:

a) transmit and/or receive pulses (e.g., microwave pulses, microwave signals, control signals, and/or another pulse) to and/or from device 200, first dispersion resonators 112, and/or second dispersion resonators 114; and/or b) transmit and/or receive a laser of microwave light to and/or from device 200, first dispersion resonators 112, and/or second dispersion resonators 114.

In the embodiments described above, such pulses and/or laser of microwave light can constitute a pump tone that can be provided to, for instance, transmission line 106 of device 200. In these embodiments, based on device 200 (e.g., transmission line 106) receiving a pump tone as described above, second dispersion resonators 114 can reduce phase-mismatch to provide a defined four-wave mixing operation (e.g., an optimized four-wave mixing operation) and/or amplification of a quantum signal and first dispersion resonators 112 can generate sideband suppression.

In an embodiment, based on device 200 (e.g., transmission line 106) receiving a pump tone as described above, second dispersion resonators 114 can reduce phase-mismatch to provide a defined four-wave mixing operation (e.g., an optimized four-wave mixing operation) and/or amplification of a quantum signal by counteracting the dispersion of transmission line 106. In this embodiment, based on device 200 (e.g., transmission line 106) receiving a pump tone as described above, first dispersion resonators 112 can generate sideband suppression to suppress and/or suppress generation of a third order harmonic of the pump tone applied to device 200 (e.g., to transmission line 106), a third order intermodulation product, and/or a fifth order intermodulation product. In various embodiments: the third order harmonic of the pump tone applied to device 200 can be denoted as 3ωₚ, where ωₚ denotes pump angular frequency of the pump tone; the third order intermodulation product can be denoted as 2ωₚ+ωₛ, where ωₛ denotes signal angular frequency; and the fifth order intermodulation product can be denoted as 4ωₚ−ωₛ. The idler angular frequency can be denoted as ωᵢ, where ωᵢ=2ωₚ−ωₛ.

To generate such sideband suppression, based on device 200 (e.g., transmission line 106) receiving a pump tone as described above, first dispersion resonators 112 can each operate at a defined operating frequency (e.g., a defined resonant frequency) to create a stopband that increases dispersion and attenuates the third order harmonic of the pump tone applied to device 200, the third order intermodulation product, and/or the fifth order intermodulation product. For example, first dispersion resonators 112 can each operate at a defined operating frequency ranging from approximately 1 GHz to approximately 100 GHz to create such a stopband that increases dispersion and attenuates the third order harmonic of the pump tone applied to device 200, the third order intermodulation product, and/or the fifth order intermodulation product. In this example, such a stopband can increase dispersion to limit generation of the third order harmonic of the pump tone applied to device 200, the third order intermodulation product, and/or the fifth order intermodulation product.

In an example, to create the above described stopband, first dispersion resonators 112 can each operate at a defined operating frequency that is approximately equal to, for instance, the third order harmonic of the pump tone applied to device 200, the third order intermodulation product, and/or the fifth order intermodulation product. In this example, the third order harmonic of the pump tone applied to device 200, the third order intermodulation product, and/or the fifth order intermodulation product constitute higher order sidebands that are sources of quantum noise that device 200 can reduce by limiting signal coupling to these modes. In this example, based on each first dispersion resonator 112 operating at such a defined operating frequency to create such a stopband, device 200 and/or first dispersion resonators 112 can thereby improve at least one of: quantum efficiency, gain per unit length, stability, or noise performance of device 200. In various embodiments, such a defined operating frequency of each of the first dispersion resonators 112 can be set during design and/or fabrication of device 200.

In an embodiment, based on device 200 (e.g., transmission line 106) receiving a pump tone as described above, second dispersion resonators 114 can minimize the phase-mismatch between the input signal, the pump tone, and an idler that is generated and first dispersion resonators 112 can maximize phase-mismatch corresponding to a four-wave mixing generation of a third order harmonic of the pump tone applied to device 200, a third order intermodulation product, and/or a fifth order intermodulation product. For example, the locations of first dispersion resonators 112 and/or second dispersion resonators 114 on device 200 with respect to unit cells 102 can affect the respective coupling strength of first dispersion resonators 112 and/or second dispersion resonators 114 to transmission line 106. In the example embodiment depicted in FIG. 2, second dispersion resonators 114 can be positioned on device 200 such that when device 200 (e.g., transmission line 106) receives a pump tone as described above, second dispersion resonators 114 can minimize the phase-mismatch between the input signal, the pump tone, and an idler that is generated. In this example embodiment, first dispersion resonators 112 can be positioned on device 200 such that when device 200 (e.g., transmission line 106) receives a pump tone as described above, first dispersion resonators 112 can maximize phase-mismatch corresponding to a four-wave mixing generation of a third order harmonic of the pump tone applied to device 200, a third order intermodulation product, and/or a fifth order intermodulation product.

To determine desired coupling strengths of first dispersion resonators 112 and/or second dispersion resonators 114 and/or to determine the desired locations of such resonators on device 200 (e.g., the RPM periods of such resonators), an entity as defined herein that implements device 200 can use phase-mismatch calculations. For example, such an entity can use Equations (1), (2), (3), and/or (4) defined above with reference to the example embodiment illustrated in FIG. 1 to perform such phase-mismatch calculations, to determine desired coupling strengths of first dispersion resonators 112 and/or second dispersion resonators 114, and/or to determine the desired locations of such resonators on device 200 (e.g., to determine the desired RPM periods of such resonators). For instance, such an entity can use Equation (1) defined above to minimize phase-mismatch corresponding to operation of second dispersion resonators 114 by minimizing |Δk|. In another example, such an entity can use Equations (2), (3), and (4) defined above to maximize phase-mismatch corresponding to operation of first dispersion resonators 112 by maximizing |Δk_{IM3}|, |Δk_{IM5}|, and |Δkₚ₃|.

Fabrication of device 200 can comprise multi-step sequences of, for example, photolithographic and/or chemical processing steps that facilitate gradual creation of electronic-based systems, devices, components, and/or circuits in a semiconducting and/or a superconducting device (e.g., an integrated circuit). For instance, device 200 can be fabricated on one or more substrates (e.g., a silicon (Si) substrates, and/or another substrate) by employing techniques including, but not limited to: photolithography, microlithography, nanolithography, nanoimprint lithography, photomasking techniques, patterning techniques, photoresist techniques (e.g., positive-tone photoresist, negative-tone photoresist, hybrid-tone photoresist, and/or another photoresist technique), etching techniques (e.g., reactive ion etching (RIE), dry etching, wet etching, ion beam etching, plasma etching, laser ablation, and/or another etching technique), evaporation techniques, sputtering techniques, plasma ashing techniques, thermal treatments (e.g., rapid thermal anneal, furnace anneals, thermal oxidation, and/or another thermal treatment), chemical vapor deposition (CVD), atomic layer deposition (ALD), physical vapor deposition (PVD), molecular beam epitaxy (MBE), electrochemical deposition (ECD), chemical-mechanical planarization (CMP), backgrinding techniques, and/or another technique for fabricating an integrated circuit.

Device 200 can be fabricated using various materials. For example, device 200 can be fabricated using materials of one or more different material classes including, but not limited to: conductive materials, semiconducting materials, superconducting materials, dielectric materials, polymer materials, organic materials, inorganic materials, non-conductive materials, and/or another material that can be utilized with one or more of the techniques described above for fabricating an integrated circuit.

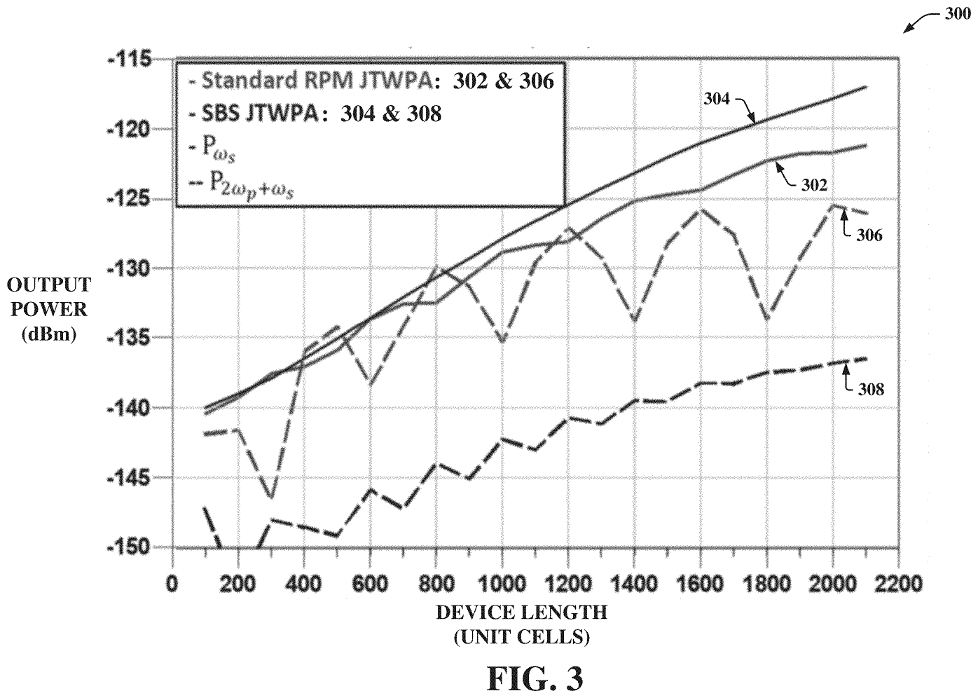

FIG. 3 illustrates an example, non-limiting graph 300 that can facilitate a JTWPA device with sideband suppression in accordance with one or more embodiments described herein. Repetitive description of like elements and/or processes employed in respective embodiments is omitted for sake of brevity.

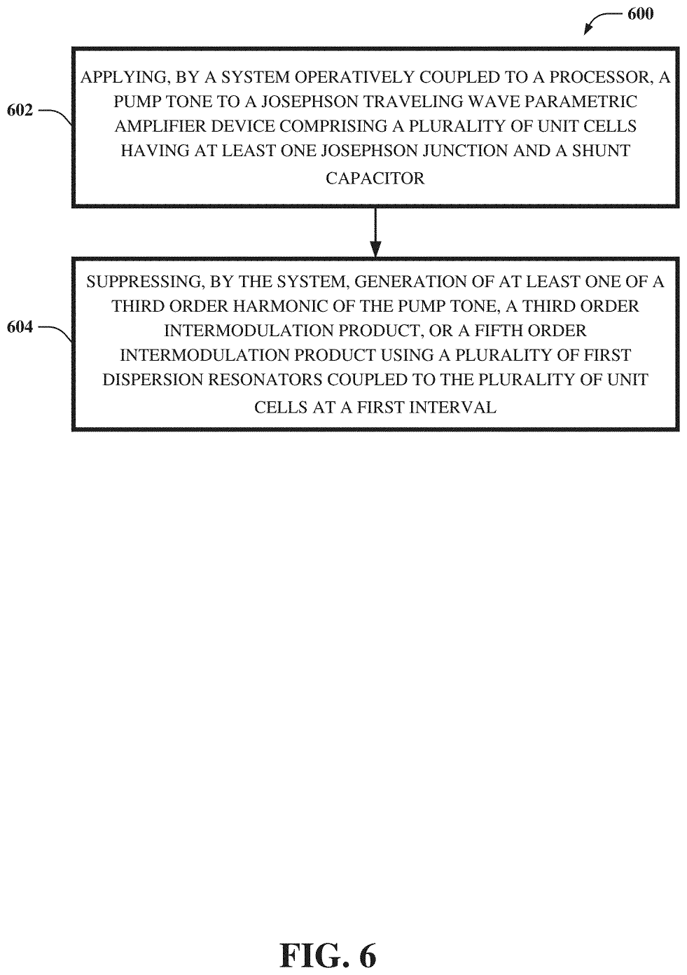

Graph 300 can comprise results data yielded from implementing (e.g., simulating, quantizing, and/or testing) one or more embodiments of the subject disclosure described herein. For example, graph 300 can comprise results data yielded from simulating device 100 and/or device 200 as described above with reference to FIGS. 1 and 2, respectively, and/or in accordance with one or more other embodiments of the subject disclosure described herein (e.g., in accordance with computer-implemented methods 600, 700, 800, and/or 900 described below with reference to FIGS. 6, 7, 8, and 9, respectively). In the example, non-limiting graph 300 depicted in FIG. 3, device 100 and/or device 200 are denoted as a sideband suppression (SBS) JTWPA device and the results data corresponding to such a device are rendered on graph 300 as plot 304 and plot 308. In the example, non-limiting graph 300 depicted in FIG. 3, for purposes of comparison, plot 302 and plot 306 of graph 300 comprise results data yielded from implementing a standard resonant phase-matching (RPM) JTWPA device.

Plot 302 and plot 306 illustrated in the example, non-limiting graph 300 depicted in FIG. 3 represent results data generated by simulating operation of a standard RPM JTWPA device comprising one or more second dispersion resonators 114. Plot 304 and plot 308 illustrated in the example, non-limiting graph 300 depicted in FIG. 3 represent results data generated by simulating operation of device 100 and/or device 200 comprising one or more first dispersion resonators 112 and one or more second dispersion resonators 114. In the example, non-limiting graph 300 depicted in FIG. 3, such results data are rendered on graph 300 as a function of output power expressed in decibel-milliwatts (dBm) along the

Y-axis of graph 300 and device length expressed in unit cells (e.g., the number of unit cells 102 provided on device 100 and/or device 200) along the X-axis of graph 300. In the example, non-limiting graph 300 depicted in FIG. 3, plot 302 and plot 304 illustrate output power at a signal frequency (denoted as “P_{ω}_{ₛ}” in FIG. 3) as a function of device length. In the example, non-limiting graph 300 depicted in FIG. 3, plot 306 and plot 308 illustrate output power at a third-order intermodulation product (denoted as “P_{2ω}_{ₚ}_{+ω}_{ₛ}” in FIG. 3) as a function of device length.

As illustrated in the example, non-limiting graph 300 depicted in FIG. 3, while plot 302 is amplified along the length of the standard RPM JTWPA device to an output power of approximately −121 dBm, plot 306 has relatively high value at the output. In contrast, as illustrated in the example, non-limiting graph 300 depicted in FIG. 3, plot 304 is amplified along the length of the device 100 and/or device 200 (denoted as “SBS JTWPA” in FIG. 3) to an output power of approximately −117 dBm, while plot 308 is at a relatively low value at the output compared to plot 306. It should be appreciated that the suppression of such oscillations of output power in plot 304 compared to plot 302 is indicative of the suppression coupling of the signal to the undesired sidebands and consequently sideband suppression that can be provided by device 100 and/or device 200 in accordance with one or more embodiments of the subject disclosure. Additionally, or alternatively, as illustrated in the example, non-limiting graph 300 depicted in FIG. 3, it should also be appreciated that plot 304 has an improved gain per unit length compared to plot 302, which is indicative of an improvement by device 100 and/or device 200 when compared to the standard RPM JTWPA device.

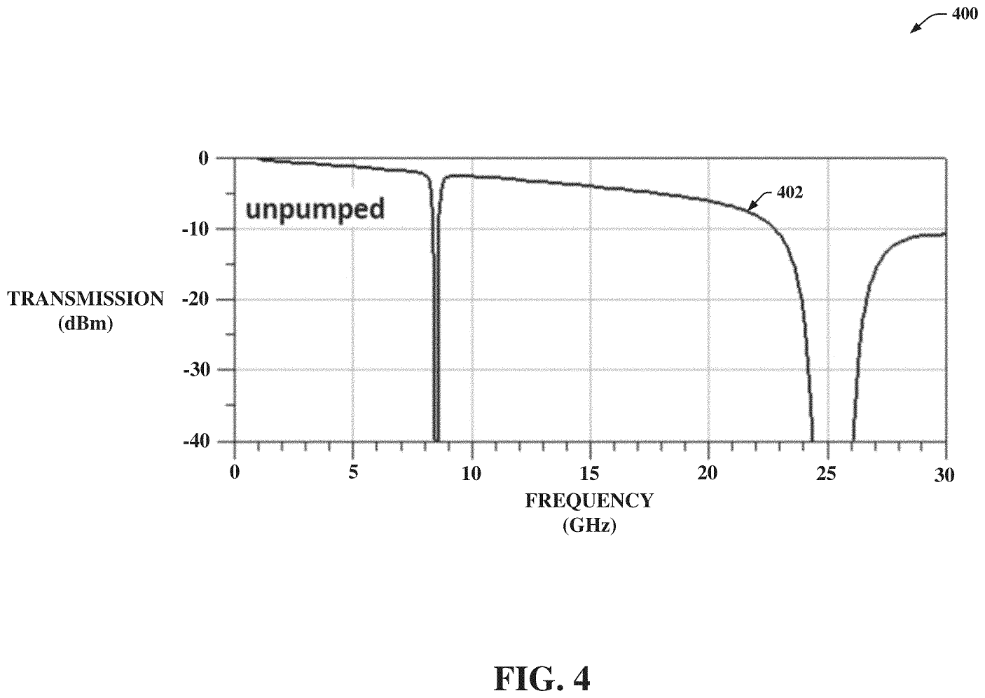

FIG. 4 illustrates an example, non-limiting graph 400 that can facilitate a JTWPA device with sideband suppression in accordance with one or more embodiments described herein. Repetitive description of like elements and/or processes employed in respective embodiments is omitted for sake of brevity.

Graph 400 can comprise results data yielded from implementing (e.g., simulating, quantizing, and/or testing) one or more embodiments of the subject disclosure described herein. For example, graph 400 can comprise results data yielded from simulating device 100 and/or device 200 as described above with reference to FIGS. 1 and 2, respectively, and/or in accordance with one or more other embodiments of the subject disclosure described herein (e.g., in accordance with computer-implemented methods 600, 700, 800, and/or 900 described below with reference to FIGS. 6, 7, 8, and 9, respectively). In the example, non-limiting graph 400 depicted in FIG. 4, such results data described above can be rendered on graph 400 as plot 402.

Plot 402 of the example, non-limiting graph 400 illustrated in FIG. 4 depicts an unpumped device 100 or an unpumped device 200 as a function of transmission expressed in decibels (dB) along the Y-axis of graph 400 and frequency expressed in gigahertz (GHz) along the X-axis of graph 400. The simulated performance of second dispersion resonators 114 is illustrated on plot 402 at approximately 8.5 GHz, where second dispersion resonators 114 minimize phase-mismatch between the input signal, the pump tone, and an idler that is generated. The simulated performance of first dispersion resonators 112 is illustrated on plot 402 at approximately 25.0 GHz, where first dispersion resonators 112 maximize phase-mismatch corresponding to a four-wave mixing generation of a third order harmonic of a pump tone applied to device 200, a third order intermodulation product, and/or a fifth order intermodulation product.

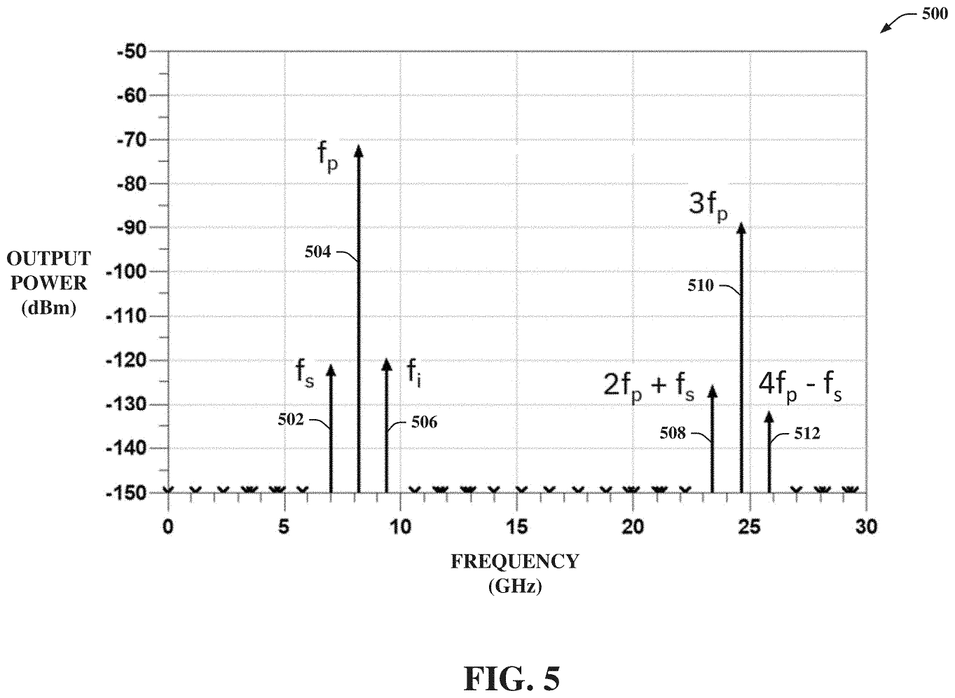

FIG. 5 illustrates an example, non-limiting graph 500 that can facilitate a JTWPA device with sideband suppression in accordance with one or more embodiments described herein. Repetitive description of like elements and/or processes employed in respective embodiments is omitted for sake of brevity.

Graph 500 can comprise results data yielded from implementing (e.g., simulating, quantizing, and/or testing) one or more embodiments of the subject disclosure described herein. For example, graph 500 can comprise results data yielded from simulating device 100 and/or device 200 as described above with reference to FIGS. 1 and 2, respectively, and/or in accordance with one or more other embodiments of the subject disclosure described herein (e.g., in accordance with computer-implemented methods 600, 700, 800, and/or 900 described below with reference to FIGS. 6, 7, 8, and 9, respectively). In the example, non-limiting graph 500 depicted in FIG. 4, such results data described above can be rendered on graph 500 as bars 502, 504, 506, 508, and 510.

Graph 500 corresponds to graph 400 described above with reference to FIG. 4. For instance, the example, non-limiting graph 500 illustrated in FIG. 5 depicts the output spectrum of a pumped standard RPM JTWPA device as a function of output power expressed in decibel-milliwatts (dBm) along the Y-axis of graph 500 and frequency expressed in gigahertz (GHz) along the X-axis of graph 500. Bars 502, 504, and 506 of the example, non-limiting graph 500 illustrated in FIG. 5 correspond to the simulated performance of second dispersion resonators 114 similar to the resonators illustrated on plot 402 at approximately 8.5 GHz, where second dispersion resonators 114 minimize phase-mismatch. Bars 508, 510, and 512 correspond to the simulated performance of a standard RPM JTWPA device. It should be appreciated that at the frequencies corresponding to bars 508, 510, and 512, in device 100 and/or device 200, first dispersion resonators 112 illustrated on plot 402 at approximately 25.0 GHz can attenuate and maximize phase-mismatch corresponding to the generation of a third order harmonic of a pump tone applied to device 100 and/or device 200 (denoted as “3fₚ” in FIG. 5), a third order intermodulation product (denoted as “2fₚ+fₛ” in FIG. 5), and/or a fifth order intermodulation product (denoted as “4fₚ−fₛ” in FIG. 5).

FIG. 6 illustrates a flow diagram of an example, non-limiting computer-implemented method 600 that can facilitate a JTWPA device with sideband suppression in accordance with one or more embodiments described herein. Repetitive description of like elements and/or processes employed in respective embodiments is omitted for sake of brevity.

At 602, computer-implemented method 600 can comprise applying, by a system (e.g., a system comprising, for instance, device 200 coupled to an AWG, a VNA, and/or a maser that can be coupled to computer 1012) operatively coupled to a processor (e.g., processing unit 1014), a pump tone to a Josephson traveling wave parametric amplifier device (e.g., device 100 and/or device 200) comprising a plurality of unit cells (e.g., unit cells 102) having at least one Josephson junction (e.g., Josephson junction 104) and a shunt capacitor (e.g., shunt capacitor 108).

At 604, computer-implemented method 600 can comprise suppressing, by the system (e.g., a system comprising, for instance, device 200 coupled to an AWG, a VNA, and/or a maser that can be coupled to computer 1012), generation of at least one of a third order harmonic of the pump tone, a third order intermodulation product, or a fifth order intermodulation product using a plurality of first dispersion resonators (e.g., first dispersion resonators 112) coupled to the plurality of unit cells at a first interval (e.g., a first RPM period).

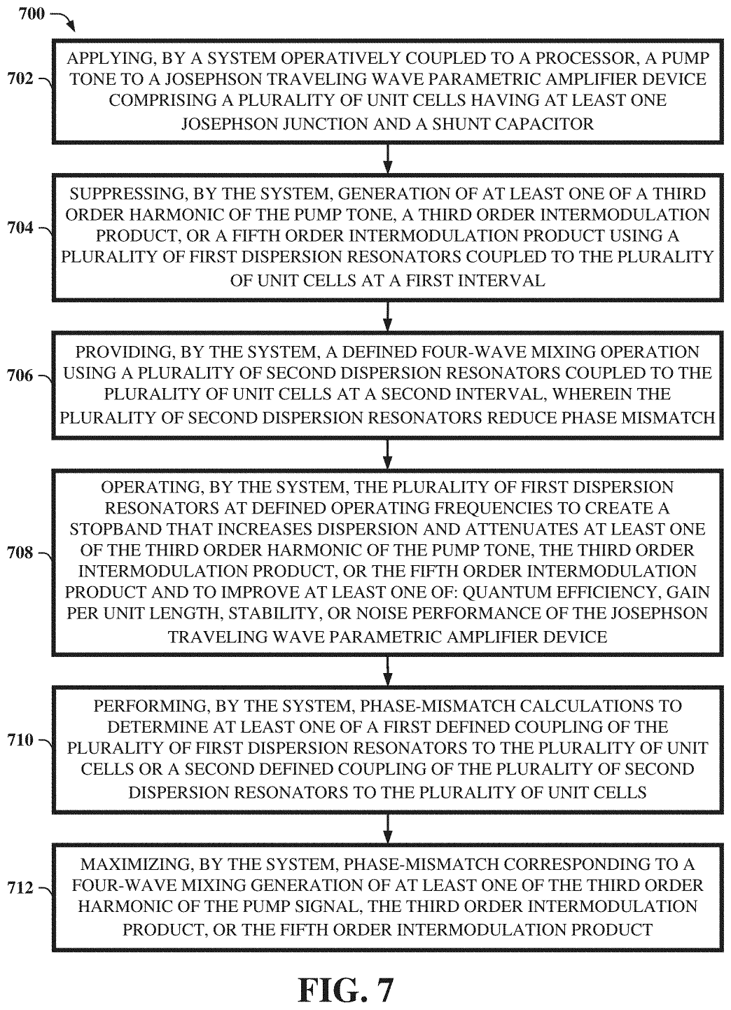

FIG. 7 illustrates a flow diagram of an example, non-limiting computer-implemented method 700 that can facilitate a JTWPA device with sideband suppression in accordance with one or more embodiments described herein. Repetitive description of like elements and/or processes employed in respective embodiments is omitted for sake of brevity.

At 702, computer-implemented method 700 can comprise applying, by a system (e.g., a system comprising, for instance, device 200 coupled to an AWG, a VNA, and/or a maser that can be coupled to computer 1012) operatively coupled to a processor (e.g., processing unit 1014), a pump tone to a Josephson traveling wave parametric amplifier device (e.g., device 100 and/or device 200) comprising a plurality of unit cells (e.g., unit cells 102) having at least one Josephson junction (e.g., Josephson junction 104) and a shunt capacitor (e.g., shunt capacitor 108).

At 704, computer-implemented method 700 can comprise suppressing, by the system (e.g., a system comprising, for instance, device 200 coupled to an AWG, a VNA, and/or a maser that can be coupled to computer 1012), generation of at least one of a third order harmonic of the pump tone, a third order intermodulation product, or a fifth order intermodulation product using a plurality of first dispersion resonators (e.g., first dispersion resonators 112) coupled to the plurality of unit cells at a first interval (e.g., a first RPM period).

At 706, computer-implemented method 700 can comprise providing, by the system (e.g., a system comprising, for instance, device 200 coupled to an AWG, a VNA, and/or a maser that can be coupled to computer 1012), a defined four-wave mixing operation using a plurality of second dispersion resonators (e.g., second dispersion resonators 114) coupled to the plurality of unit cells at a second interval (e.g., a second RPM period), where the plurality of second dispersion resonators reduce phase mismatch.

At 708, computer-implemented method 700 can comprise operating, by the system (e.g., a system comprising, for instance, device 200 coupled to an AWG, a VNA, and/or a maser that can be coupled to computer 1012), the plurality of first dispersion resonators at defined operating frequencies (e.g., defined operating frequencies ranging from approximately 1 GHz to approximately 100 GHz) to create a stopband that increases dispersion and attenuates at least one of the third order harmonic of the pump tone, the third order intermodulation product, or the fifth order intermodulation product and to improve at least one of: quantum efficiency, gain per unit length, stability, or noise performance of the Josephson traveling wave parametric amplifier device.

At 710, computer-implemented method 700 can comprise performing, by the system (e.g., a system comprising, for instance, device 200 coupled to an AWG, a VNA, and/or a maser that can be coupled to computer 1012), phase-mismatch calculations (e.g., using Equations (1), (2), (3), and/or (4) defined above) to determine at least one of a first defined coupling of the plurality of first dispersion resonators to the plurality of unit cells or a second defined coupling of the plurality of second dispersion resonators to the plurality of unit cells.

At 712, computer-implemented method 700 can comprise maximizing, by the system (e.g., a system comprising, for instance, device 200 coupled to an AWG, a VNA, and/or a maser that can be coupled to computer 1012), phase-mismatch corresponding to a four-wave mixing generation of at least one of the third order harmonic of the pump tone, the third order intermodulation product, or the fifth order intermodulation product.

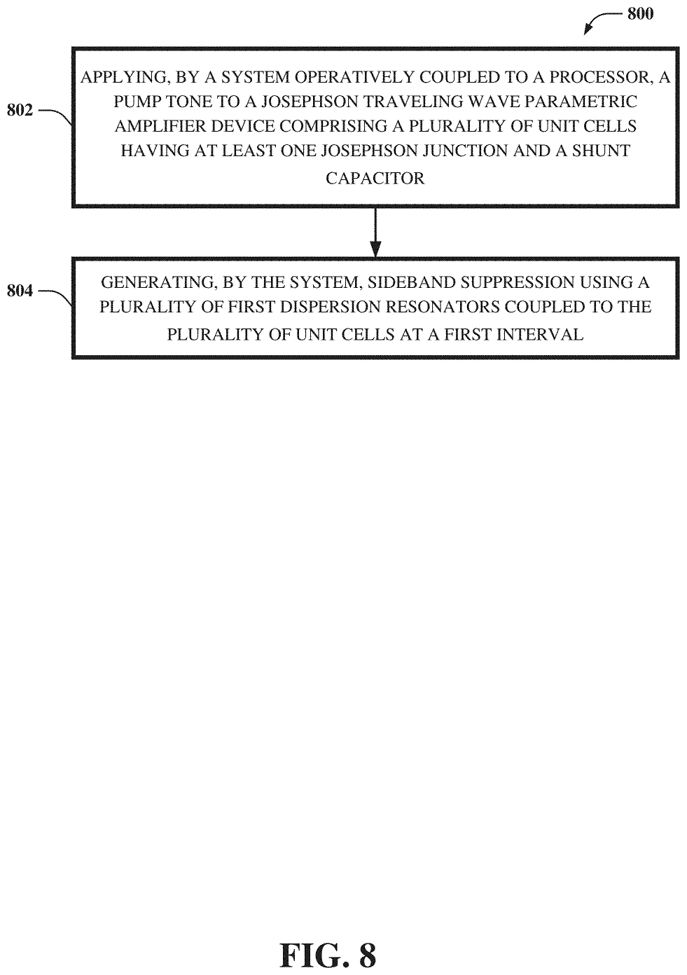

FIG. 8 illustrates a flow diagram of an example, non-limiting computer-implemented method 800 that can facilitate a JTWPA device with sideband suppression in accordance with one or more embodiments described herein. Repetitive description of like elements and/or processes employed in respective embodiments is omitted for sake of brevity.

At 802, computer-implemented method 800 can comprise applying, by a system (e.g., a system comprising, for instance, device 200 coupled to an AWG, a VNA, and/or a maser that can be coupled to computer 1012) operatively coupled to a processor (e.g., processing unit 1014), a pump tone to a Josephson traveling wave parametric amplifier device (e.g., device 100 and/or device 200) comprising a plurality of unit cells (e.g., unit cells 102) having at least one Josephson junction (e.g., Josephson junction 104) and a shunt capacitor (e.g., shunt capacitor 108).

At 804, computer-implemented method 800 can comprise generating, by the system (e.g., a system comprising, for instance, device 200 coupled to an AWG, a VNA, and/or a maser that can be coupled to computer 1012), sideband suppression using a plurality of first dispersion resonators (e.g., first dispersion resonators 112) coupled to the plurality of unit cells at a first interval (e.g., a first RPM period).

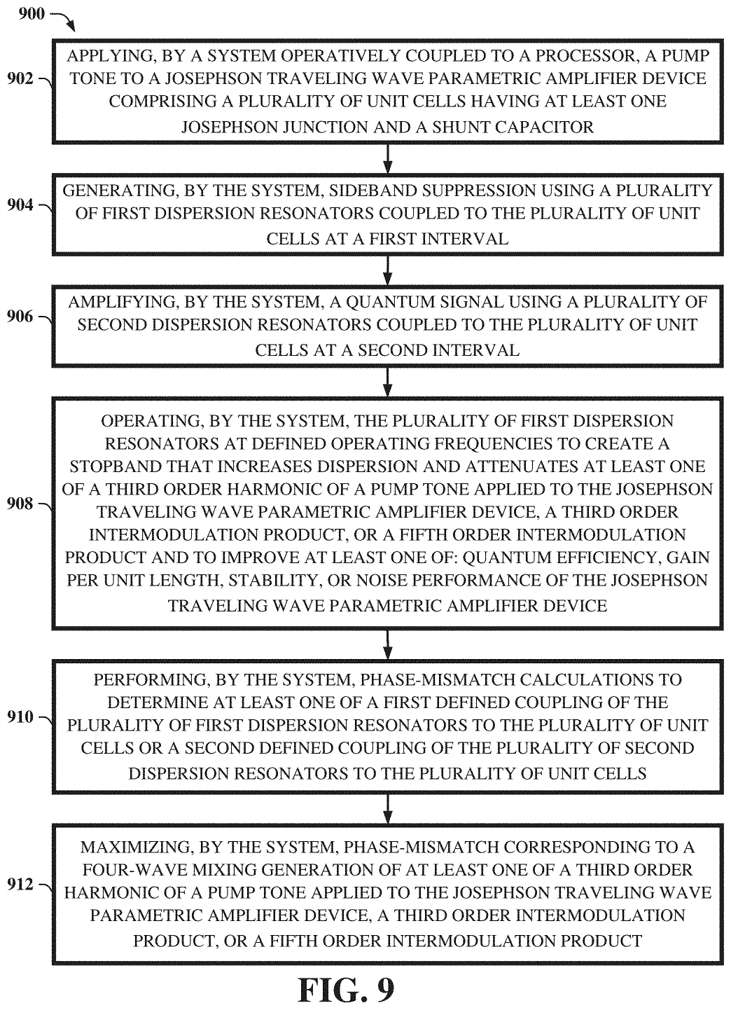

FIG. 9 illustrates a flow diagram of an example, non-limiting computer-implemented method 900 that can facilitate a JTWPA device with sideband suppression in accordance with one or more embodiments described herein. Repetitive description of like elements and/or processes employed in respective embodiments is omitted for sake of brevity.

At 902, computer-implemented method 900 can comprise applying, by a system (e.g., a system comprising, for instance, device 200 coupled to an AWG, a VNA, and/or a maser that can be coupled to computer 1012) operatively coupled to a processor (e.g., processing unit 1014), a pump tone to a Josephson traveling wave parametric amplifier device (e.g., device 100 and/or device 200) comprising a plurality of unit cells (e.g., unit cells 102) having at least one Josephson junction (e.g., Josephson junction 104) and a shunt capacitor (e.g., shunt capacitor 108).

At 904, computer-implemented method 900 can comprise generating, by the system (e.g., a system comprising, for instance, device 200 coupled to an AWG, a VNA, and/or a maser that can be coupled to computer 1012), sideband suppression using a plurality of first dispersion resonators (e.g., first dispersion resonators 112) coupled to the plurality of unit cells at a first interval (e.g., a first RPM period).

At 906, computer-implemented method 900 can comprise amplifying, by the system (e.g., a system comprising, for instance, device 200 coupled to an AWG, a VNA, and/or a maser that can be coupled to computer 1012), a quantum signal using a plurality of second dispersion resonators (e.g., second dispersion resonators 114) coupled to the plurality of unit cells at a second interval (e.g., a second RPM period).

At 908, computer-implemented method 900 can comprise operating, by the system (e.g., a system comprising, for instance, device 200 coupled to an AWG, a VNA, and/or a maser that can be coupled to computer 1012), the plurality of first dispersion resonators at defined operating frequencies (e.g., defined operating frequencies ranging from approximately 1 GHz to approximately 100 GHz) to create a stopband that increases dispersion and attenuates at least one of a third order harmonic of a pump tone applied to the Josephson traveling wave parametric amplifier device, a third order intermodulation product, or a fifth order intermodulation product and to improve at least one of: quantum efficiency, gain per unit length, stability, or noise performance of the Josephson traveling wave parametric amplifier device.

At 910, computer-implemented method 900 can comprise performing, by the system (e.g., a system comprising, for instance, device 200 coupled to an AWG, a VNA, and/or a maser that can be coupled to computer 1012), phase-mismatch calculations (e.g., using Equations (1), (2), (3), and/or (4) defined above) to determine at least one of a first defined coupling of the plurality of first dispersion resonators to the plurality of unit cells or a second defined coupling of the plurality of second dispersion resonators to the plurality of unit cells.

At 912, computer-implemented method 900 can comprise maximizing, by the system (e.g., a system comprising, for instance, device 200 coupled to an AWG, a VNA, and/or a maser that can be coupled to computer 1012), phase-mismatch corresponding to a four-wave mixing generation of at least one of a third order harmonic of a pump tone applied to the Josephson traveling wave parametric amplifier device, a third order intermodulation product, or a fifth order intermodulation product.

Device 100 and/or device 200 can be associated with various technologies. For example, device 100 and/or device 200 can be associated with quantum computing technologies, JTWPA device technologies, quantum hardware and/or software technologies, quantum circuit technologies, superconducting circuit technologies, low temperature electronics technologies, precision measurement technologies, radio astronomy technologies, dark matter detection technologies, machine learning technologies, artificial intelligence technologies, cloud computing technologies, and/or other technologies.

Device 100 and/or device 200 can provide technical improvements to systems, devices, components, operational steps, and/or processing steps associated with the various technologies identified above. For example, device 100 and/or device 200 can provide a four-wave mixing operation to amplify a quantum signal and can further provide sideband suppression of a third order harmonic of a pump tone applied to device 100 and/or device 200, a third order intermodulation product, and/or a fifth order intermodulation product. In this example, such sideband suppression can thereby improve quantum efficiency, gain per unit length, stability, and/or noise performance of device 100 and/or device 200. In this example, by providing the above described improvements, device 100 and/or device 200 can thereby comprise a reduced length and/or a reduced footprint size in comparison to existing JTWPA devices, which can facilitate practical engineering of and/or efficient operation of (e.g., with relatively high readout fidelities) quantum systems comprising a relatively large number of qubits (e.g., 1,000 qubits or more), device 100, and/or device 200.

Device 100 and/or device 200 can provide technical improvements to a processing unit (e.g., a quantum processor comprising device 100 and/or device 200) that can be associated with device 100 and/or device 200. For example, as described above, device 100 and/or device 200 can provide sideband suppression to improve quantum efficiency, gain per unit length, stability, and/or noise performance of device 100 and/or device 200. In this example, by providing such improvements, device 100 and/or device 200 can facilitate improved efficiency, performance, accuracy, and/or speed of a quantum processor comprising device 100 and/or device 200. In this example, as device 100 and/or device 200 can comprise a reduced length and/or a reduced footprint size in comparison to existing

JTWPA devices, device 100 and/or device 200 can further enable a reduced size of such a quantum processor comprising device 100 and/or device 200.

Based on providing the above described sideband suppression, a practical application of device 100 and/or device 200 is that they can be implemented in a quantum device (e.g., a quantum processor, a quantum computer, and/or another quantum device) to reduce the size of the quantum device, as well as to enable it to more quickly and more efficiently compute, with improved fidelity and/or accuracy, one or more solutions (e.g., heuristic(s)) to a variety of problems ranging in complexity (e.g., an estimation problem, an optimization problem, and/or another problem) in a variety of domains (e.g., finance, chemistry, medicine, and/or another domain). For example, based on providing the above described sideband suppression, a practical application of device 100 and/or device 200 is that they can be implemented in, for instance, a quantum processor to reduce the size of such a quantum processor and to enable it to more quickly and more efficiently compute, with improved fidelity and/or accuracy, one or more solutions (e.g., heuristic(s)) to an optimization problem in the domain of chemistry, medicine, and/or finance, where such a solution can be used to engineer, for instance, a new chemical compound, a new medication, and/or a new options pricing system and/or method.

It should be appreciated that device 100 and/or device 200 provide a new approach driven by relatively new quantum computing technologies. For example, device 100 and/or device 200 provide a new approach to perform a four-wave mixing operation to amplify a quantum signal and suppress sidebands such as, for instance, a third order harmonic of a pump tone applied to device 100 and/or device 200, a third order intermodulation product, and/or a fifth order intermodulation product. In this example, such a new approach to amplify a quantum signal while suppressing such sidebands can enable faster and more efficient quantum computations with improved accuracy using a quantum processor comprising a relatively large number of qubits (e.g., 1,000 qubits or more), device 100, and/or device 200.

Device 100 and/or device 200 can employ hardware and/or software to solve problems that are highly technical in nature, that are not abstract and that cannot be performed as a set of mental acts by a human. In some embodiments, one or more of the processes described herein can be performed by one or more specialized computers (e.g., a specialized processing unit, a specialized classical computer, a specialized quantum computer, and/or another specialized computer) to execute defined tasks related to the various technologies identified above. Device 100 and/or device 200 can be employed to solve new problems that arise through advancements in technologies mentioned above, employment of quantum computing systems, cloud computing systems, computer architecture, and/or another technology.

It is to be appreciated that device 100 and/or device 200 can utilize various combinations of electrical components, mechanical components, and circuitry that cannot be replicated in the mind of a human or performed by a human, as the various operations that can be executed by device 100 and/or device 200 are operations that are greater than the capability of a human mind. For instance, the amount of data processed, the speed of processing such data, or the types of data processed by device 100 and/or device 200 over a certain period of time can be greater, faster, or different than the amount, speed, or data type that can be processed by a human mind over the same period of time.

According to several embodiments, device 100 and/or device 200 can also be fully operational towards performing one or more other functions (e.g., fully powered on, fully executed, and/or another function) while also performing the various operations described herein. It should be appreciated that such simultaneous multi-operational execution is beyond the capability of a human mind. It should also be appreciated that device 100 and/or device 200 can include information that is impossible to obtain manually by an entity, such as a human user. For example, the type, amount, and/or variety of information included in device 100 and/or device 200 can be more complex than information obtained manually by a human user.

In order to provide a context for the various aspects of the disclosed subject matter, FIG. 10 as well as the following discussion are intended to provide a general description of a suitable environment in which the various aspects of the disclosed subject matter can be implemented. FIG. 10 illustrates a block diagram of an example, non-limiting operating environment in which one or more embodiments described herein can be facilitated. For example, as described below, operating environment 1000 can be used to implement the example, non-limiting multi-step fabrication sequences described above with reference to FIGS. 1 and 2 that can be implemented to fabricate device 100 and/or device 200 in accordance with one or more embodiments of the subject disclosure as described herein. In another example, as described below, operating environment 1000 can be used to implement one or more of the example, non-limiting computer-implemented methods 600, 700, 800, and/or 900 described above with reference to FIGS. 6, 7, 8, and 9, respectively. Repetitive description of like elements and/or processes employed in other embodiments described herein is omitted for sake of brevity.

The example, non-limiting multi-step fabrication sequences described above with reference to FIGS. 1 and 2, which can be implemented to fabricate device 100 and/or device 200, can be implemented by a computing system (e.g., operating environment 1000 illustrated in FIG. 10 and described below) and/or a computing device (e.g., computer 1012 illustrated in FIG. 10 and described below). In non-limiting example embodiments, such a computing system (e.g., operating environment 1000) and/or such a computing device (e.g., computer 1012) can comprise one or more processors and one or more memory devices that can store executable instructions thereon that, when executed by the one or more processors, can facilitate performance of the example, non-limiting multi-step fabrication sequences described above with reference to FIGS. 1 and 2. As a non-limiting example, the one or more processors can facilitate performance of the example, non-limiting multi-step fabrication sequences described above with reference to FIGS. 1 and 2 by directing and/or controlling one or more systems and/or equipment operable to perform semiconductor and/or superconductor device fabrication.

In another example, one or more of the example, non-limiting computer-implemented methods 600, 700, 800, and/or 900 described above with reference to FIGS. 6, 7, 8, and 9, respectively, can also be implemented (e.g., executed) by operating environment 1000. As a non-limiting example, the one or more processors of such a computing device (e.g., computer 1012) can facilitate performance of one or more of the example, non-limiting computer implemented methods 600, 700, 800, and/or 900 described above with reference to FIGS. 6, 7, 8, and 9, respectively, by directing and/or controlling one or more systems and/or equipment (e.g., one or more types of the external device defined herein such as, for instance, an AWG, a VNA, a maser, and/or another external device) operable to perform the operations and/or routines of such computer-implemented method(s).

For simplicity of explanation, the computer-implemented methodologies are depicted and described as a series of acts. It is to be understood and appreciated that the subject innovation is not limited by the acts illustrated and/or by the order of acts, for example acts can occur in various orders and/or concurrently, and with other acts not presented and described herein. Furthermore, not all illustrated acts can be required to implement the computer-implemented methodologies in accordance with the disclosed subject matter. In addition, those skilled in the art will understand and appreciate that the computer-implemented methodologies could alternatively be represented as a series of interrelated states via a state diagram or events. Additionally, it should be further appreciated that the computer-implemented methodologies disclosed hereinafter and throughout this specification are capable of being stored on an article of manufacture to facilitate transporting and transferring such computer-implemented methodologies to computers. The term article of manufacture, as used herein, is intended to encompass a computer program accessible from any computer-readable device or storage media.

With reference to FIG. 10, a suitable operating environment 1000 to implement various aspects of this disclosure can also include a computer 1012. The computer 1012 can also include a processing unit 1014, a system memory 1016, and a system bus 1018. The system bus 1018 couples system components including, but not limited to, the system memory 1016 to the processing unit 1014. The processing unit 1014 can be any of various available processors. Dual microprocessors and other multiprocessor architectures also can be employed as the processing unit 1014. The system bus 1018 can be any of several types of bus structure(s) including the memory bus or memory controller, a peripheral bus or external bus, and/or a local bus using any variety of available bus architectures including, but not limited to, Industrial Standard Architecture (ISA), Micro-Channel Architecture (MSA), Extended ISA (EISA), Intelligent Drive Electronics (IDE), VESA Local Bus (VLB), Peripheral Component Interconnect (PCI), Card Bus, Universal Serial Bus (USB), Advanced Graphics Port (AGP), Firewire (IEEE 1394), and Small Computer Systems Interface (SCSI).

The system memory 1016 can also include volatile memory 1020 and nonvolatile memory 1022. The basic input/output system (BIOS), containing the basic routines to transfer information between elements within the computer 1012, such as during start-up, is stored in nonvolatile memory 1022. Computer 1012 can also include removable/non-removable, volatile/non-volatile computer storage media. FIG. 10 illustrates, for example, a disk storage 1024. Disk storage 1024 can also include, but is not limited to, devices like a magnetic disk drive, floppy disk drive, tape drive, Jaz drive, Zip drive, LS-100 drive, flash memory card, or memory stick. The disk storage 1024 also can include storage media separately or in combination with other storage media. To facilitate connection of the disk storage 1024 to the system bus 1018, a removable or non-removable interface is typically used, such as interface 1026. FIG. 10 also depicts software that acts as an intermediary between users and the basic computer resources described in the suitable operating environment 1000. Such software can also include, for example, an operating system 1028. Operating system 1028, which can be stored on disk storage 1024, acts to control and allocate resources of the computer 1012.

System applications 1030 take advantage of the management of resources by operating system 1028 through program modules 1032 and program data 1034, e.g., stored either in system memory 1016 or on disk storage 1024. It is to be appreciated that this disclosure can be implemented with various operating systems or combinations of operating systems. A user enters commands or information into the computer 1012 through input device(s) 1036. Input devices 1036 include, but are not limited to, a pointing device such as a mouse, trackball, stylus, touch pad, keyboard, microphone, joystick, game pad, satellite dish, scanner, TV tuner card, digital camera, digital video camera, web camera, and the like. These and other input devices connect to the processing unit 1014 through the system bus 1018 via interface port(s) 1038. Interface port(s) 1038 include, for example, a serial port, a parallel port, a game port, and a universal serial bus (USB). Output device(s) 1040 use some of the same type of ports as input device(s) 1036. Thus, for example, a USB port can be used to provide input to computer 1012, and to output information from computer 1012 to an output device 1040. Output adapter 1042 is provided to illustrate that there are some output devices 1040 like monitors, speakers, and printers, among other output devices 1040, which require special adapters. The output adapters 1042 include, by way of illustration and not limitation, video and sound cards that provide a means of connection between the output device 1040 and the system bus 1018. It should be noted that other devices and/or systems of devices provide both input and output capabilities such as remote computer(s) 1044.

Computer 1012 can operate in a networked environment using logical connections to one or more remote computers, such as remote computer(s) 1044. The remote computer(s) 1044 can be a computer, a server, a router, a network PC, a workstation, a microprocessor based appliance, a peer device or other common network node and the like, and typically can also include many or all of the elements described relative to computer 1012. For purposes of brevity, only a memory storage device 1046 is illustrated with remote computer(s) 1044. Remote computer(s) 1044 is logically connected to computer 1012 through a network interface 1048 and then physically connected via communication connection 1050. Network interface 1048 encompasses wire and/or wireless communication networks such as local-area networks (LAN), wide-area networks (WAN), cellular networks, and/or another communication network. LAN technologies include Fiber Distributed Data Interface (FDDI), Copper Distributed Data Interface (CDDI), Ethernet, Token Ring and the like. WAN technologies include, but are not limited to, point-to-point links, circuit switching networks like Integrated Services Digital Networks (ISDN) and variations thereon, packet switching networks, and Digital Subscriber Lines (DSL). Communication connection(s) 1050 refers to the hardware/software employed to connect the network interface 1048 to the system bus 1018. While communication connection 1050 is shown for illustrative clarity inside computer 1012, it can also be external to computer 1012. The hardware/software for connection to the network interface 1048 can also include, for exemplary purposes only, internal and external technologies such as, modems including regular telephone grade modems, cable modems and DSL modems, ISDN adapters, and Ethernet cards.

The present invention may be a system, a method, an apparatus and/or a computer program product at any possible technical detail level of integration. The computer program product can include a computer readable storage medium (or media) having computer readable program instructions thereon for causing a processor to carry out aspects of the present invention. The computer readable storage medium can be a tangible device that can retain and store instructions for use by an instruction execution device. The computer readable storage medium can be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium can also include the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network can comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device. Computer readable program instructions for carrying out operations of the present invention can be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions can execute entirely on the user's computer, partly on the user's computer, as a stand-alone software package, partly on the user's computer and partly on a remote computer or entirely on the remote computer or server. In the latter scenario, the remote computer can be connected to the user's computer through any type of network, including a local area network (LAN) or a wide area network (WAN), or the connection can be made to an external computer (for example, through the Internet using an Internet Service Provider). In some embodiments, electronic circuitry including, for example, programmable logic circuitry, field-programmable gate arrays (FPGA), or programmable logic arrays (PLA) can execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions. These computer readable program instructions can be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions can also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks. The computer readable program instructions can also be loaded onto a computer, other programmable data processing apparatus, or other device to cause a series of operational acts to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams can represent a module, segment, or portion of instructions, which comprises one or more executable instructions for implementing the specified logical function(s). In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

While the subject matter has been described above in the general context of computer-executable instructions of a computer program product that runs on a computer and/or computers, those skilled in the art will recognize that this disclosure also can or can be implemented in combination with other program modules. Generally, program modules include routines, programs, components, data structures, and/or entities that perform particular tasks and/or implement particular abstract data types. Moreover, those skilled in the art will appreciate that the inventive computer-implemented methods can be practiced with other computer system configurations, including single-processor or multiprocessor computer systems, mini-computing devices, mainframe computers, as well as computers, hand-held computing devices (e.g., PDA, phone), microprocessor-based or programmable consumer or industrial electronics, and the like. The illustrated aspects can also be practiced in distributed computing environments in which tasks are performed by remote processing devices that are linked through a communications network. However, some, if not all aspects of this disclosure can be practiced on stand-alone computers. In a distributed computing environment, program modules can be located in both local and remote memory storage devices. For example, in one or more embodiments, computer executable components can be executed from memory that can include or be comprised of one or more distributed memory units. As used herein, the term “memory” and “memory unit” are interchangeable. Further, one or more embodiments described herein can execute code of the computer executable components in a distributed manner, e.g., multiple processors combining or working cooperatively to execute code from one or more distributed memory units. As used herein, the term “memory” can encompass a single memory or memory unit at one location or multiple memories or memory units at one or more locations.

As used in this application, the terms “component,” “system,” “platform,” “interface,” and the like, can refer to and/or can include a computer-related entity or an entity related to an operational machine with one or more specific functionalities. The entities disclosed herein can be either hardware, a combination of hardware and software, software, or software in execution. For example, a component can be, but is not limited to being, a process running on a processor, a processor, an object, an executable, a thread of execution, a program, and/or a computer. By way of illustration, both an application running on a server and the server can be a component. One or more components can reside within a process and/or thread of execution and a component can be localized on one computer and/or distributed between two or more computers. In another example, respective components can execute from various computer readable media having various data structures stored thereon. The components can communicate via local and/or remote processes such as in accordance with a signal having one or more data packets (e.g., data from one component interacting with another component in a local system, distributed system, and/or across a network such as the Internet with other systems via the signal). As another example, a component can be an apparatus with specific functionality provided by mechanical parts operated by electric or electronic circuitry, which is operated by a software or firmware application executed by a processor. In such a case, the processor can be internal or external to the apparatus and can execute at least a part of the software or firmware application. As yet another example, a component can be an apparatus that provides specific functionality through electronic components without mechanical parts, where the electronic components can include a processor or other means to execute software or firmware that confers at least in part the functionality of the electronic components. In an aspect, a component can emulate an electronic component via a virtual machine, e.g., within a cloud computing system.

In addition, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. Moreover, articles “a” and “an” as used in the subject specification and annexed drawings should generally be construed to mean “one or more” unless specified otherwise or clear from context to be directed to a singular form. As used herein, the terms “example” and/or “exemplary” are utilized to mean serving as an example, instance, or illustration. For the avoidance of doubt, the subject matter disclosed herein is not limited by such examples. In addition, any aspect or design described herein as an “example” and/or “exemplary” is not necessarily to be construed as preferred or advantageous over other aspects or designs, nor is it meant to preclude equivalent exemplary structures and techniques known to those of ordinary skill in the art.

As it is employed in the subject specification, the term “processor” can refer to substantially any computing processing unit or device comprising, but not limited to, single-core processors; single-processors with software multithread execution capability; multi-core processors; multi-core processors with software multithread execution capability; multi-core processors with hardware multithread technology; parallel platforms; and parallel platforms with distributed shared memory. Additionally, a processor can refer to an integrated circuit, an application specific integrated circuit (ASIC), a digital signal processor (DSP), a field programmable gate array (FPGA), a programmable logic controller (PLC), a complex programmable logic device (CPLD), a discrete gate or transistor logic, discrete hardware components, or any combination thereof designed to perform the functions described herein. Further, processors can exploit nano-scale architectures such as, but not limited to, molecular and quantum-dot based transistors, switches and gates, in order to optimize space usage or enhance performance of user equipment. A processor can also be implemented as a combination of computing processing units. In this disclosure, terms such as “store,” “storage,” “data store,” data storage,” “database,” and substantially any other information storage component relevant to operation and functionality of a component are utilized to refer to “memory components,” entities embodied in a “memory,” or components comprising a memory. It is to be appreciated that memory and/or memory components described herein can be either volatile memory or nonvolatile memory, or can include both volatile and nonvolatile memory. By way of illustration, and not limitation, nonvolatile memory can include read only memory (ROM), programmable ROM (PROM), electrically programmable ROM (EPROM), electrically erasable ROM (EEPROM), flash memory, or nonvolatile random access memory (RAM) (e.g., ferroelectric RAM (FeRAM). Volatile memory can include RAM, which can act as external cache memory, for example. By way of illustration and not limitation, RAM is available in many forms such as synchronous RAM (SRAM), dynamic RAM (DRAM), synchronous DRAM (SDRAM), double data rate SDRAM (DDR SDRAM), enhanced SDRAM (ESDRAM), Synchlink DRAM (SLDRAM), direct Rambus RAM (DRRAM), direct Rambus dynamic RAM (DRDRAM), and Rambus dynamic RAM (RDRAM). Additionally, the disclosed memory components of systems or computer-implemented methods herein are intended to include, without being limited to including, these and any other suitable types of memory.

What has been described above include mere examples of systems and computer-implemented methods. It is, of course, not possible to describe every conceivable combination of components or computer-implemented methods for purposes of describing this disclosure, but one of ordinary skill in the art can recognize that many further combinations and permutations of this disclosure are possible. Furthermore, to the extent that the terms “includes,” “has,” “possesses,” and the like are used in the detailed description, claims, appendices and drawings such terms are intended to be inclusive in a manner similar to the term “comprising” as “comprising” is interpreted when employed as a transitional word in a claim.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A device, comprising:
a plurality of unit cells including at least one Josephson junction and a shunt capacitor; and
a plurality of first dispersion resonators coupled to the plurality of unit cells at a first interval, wherein the plurality of first dispersion resonators suppress generation of at least one of a third order harmonic of a single pump tone applied to the device, a third order intermodulation product of the single pump tone applied to the device, or a fifth order intermodulation product of the single pump tone applied to the device.

2. The device of claim 1, further comprising:
a plurality of second dispersion resonators coupled to the plurality of unit cells at a second interval, wherein the plurality of second dispersion resonators reduce phase-mismatch to provide a defined four-wave mixing operation, and wherein the first interval and the second interval are the same or different.

3. The device of claim 2, wherein at least one of the plurality of first dispersion resonators or the plurality of second dispersion resonators are selected from a group consisting of a lumped element resonator and a transmission line resonator.

4. The device of claim 1, wherein the plurality of first dispersion resonators operate at defined operating frequencies to create a stopband that increases dispersion and attenuates at least one of the third order harmonic of the single pump tone, the third order intermodulation product, or the fifth order intermodulation product, and wherein the plurality of first dispersion resonators operate at the defined operating frequencies to improve at least one of: quantum efficiency, gain per unit length, stability, or noise performance of the device.

5. The device of claim 1, wherein phase-mismatch corresponding to a four-wave mixing generation of at least one of the third order harmonic of the single pump tone, the third order intermodulation product, or the fifth order intermodulation product is maximized.

6. A computer-implemented method, comprising:
applying, by a system operatively coupled to a processor, a single pump tone to a Josephson traveling wave parametric amplifier device comprising a plurality of unit cells having at least one Josephson junction and a shunt capacitor; and
suppressing, by the system, generation of at least one of a third order harmonic of the single pump tone, a third order intermodulation product, or a fifth order intermodulation product using a plurality of first dispersion resonators coupled to the plurality of unit cells at a first interval.

7. The computer-implemented method of claim 6, further comprising:
providing, by the system, a defined four-wave mixing operation using a plurality of second dispersion resonators coupled to the plurality of unit cells at a second interval, wherein the plurality of second dispersion resonators reduce phase mismatch, and wherein the first interval and the second interval are the same or different.

8. The computer-implemented method of claim 6, further comprising:
operating, by the system, the plurality of first dispersion resonators at defined operating frequencies to create a stopband that increases dispersion and attenuates at least one of the third order harmonic of the single pump tone, the third order intermodulation product, or the fifth order intermodulation product and to improve at least one of: quantum efficiency, gain per unit length, stability, or noise performance of the Josephson traveling wave parametric amplifier device.

9. The computer-implemented method of claim 7, further comprising:
performing, by the system, phase-mismatch calculations to determine at least one of a first defined coupling of the plurality of first dispersion resonators to the plurality of unit cells or a second defined coupling of the plurality of second dispersion resonators to the plurality of unit cells.

10. The computer-implemented method of claim 6, further comprising:
maximizing, by the system, phase-mismatch corresponding to a four-wave mixing generation of at least one of the third order harmonic of the single pump tone, the third order intermodulation product, or the fifth order intermodulation product.

11. A device, comprising:
a plurality of unit cells including at least one Josephson junction and a shunt capacitor; and
a plurality of first dispersion resonators coupled to the plurality of unit cells at a first interval and operative to generate sideband suppression, and a plurality of second dispersion resonators coupled to the plurality of unit cells at a second interval and operative to amplify quantum signals, and wherein the first plurality of dispersion resonators and the second plurality of dispersion resonators are operatively coupled to a single pump tone.

12. The device of claim 11, wherein the first interval and the second interval are different.

13. The device of claim 11, wherein at least one of the plurality of first dispersion resonators or the plurality of second dispersion resonators are selected from a group consisting of a lumped element resonator and a transmission line resonator.

14. The device of claim 11, wherein the plurality of first dispersion resonators operate at defined operating frequencies to create a stopband that increases dispersion and attenuates at least one of a third order harmonic of the single pump tone applied to the device, a third order intermodulation product of the single pump tone applied to the device, or a fifth order intermodulation product of the single pump tone applied to the device, and wherein the plurality of first dispersion resonators operate at the defined operating frequencies to improve at least one of: quantum efficiency, gain per unit length, stability, or noise performance of the device.

15. The device of claim 11, wherein phase-mismatch corresponding to a four-wave mixing generation of at least one of a third order harmonic of the single pump tone applied to the device, a third order intermodulation product, or a fifth order intermodulation product is maximized.

16. A computer-implemented method, comprising:
applying, by a system operatively coupled to a processor, a single pump tone to a Josephson traveling wave parametric amplifier device comprising a plurality of unit cells having at least one Josephson junction and a shunt capacitor; and
generating, by the system, sideband suppression using a plurality of first dispersion resonators coupled to the plurality of unit cells at a first interval.

17. The computer-implemented method of claim 16, further comprising:
amplifying, by the system, a quantum signal using a plurality of second dispersion resonators coupled to the plurality of unit cells at a second interval, wherein the first interval and the second interval are the same or different.

18. The computer-implemented method of claim 16, further comprising:
operating, by the system, the plurality of first dispersion resonators at defined operating frequencies to create a stopband that increases dispersion and attenuates at least one of a third order harmonic of the single pump tone applied to the Josephson traveling wave parametric amplifier device, a third order intermodulation product, or a fifth order intermodulation product and to improve at least one of: quantum efficiency, gain per unit length, stability, or noise performance of the Josephson traveling wave parametric amplifier device.

19. The computer-implemented method of claim 17, further comprising:
performing, by the system, phase-mismatch calculations to determine at least one of a first defined coupling of the plurality of first dispersion resonators to the plurality of unit cells or a second defined coupling of the plurality of second dispersion resonators to the plurality of unit cells.

20. The computer-implemented method of claim 16, further comprising:
maximizing, by the system, phase-mismatch corresponding to a four-wave mixing generation of at least one of a third order harmonic of the single pump tone applied to the Josephson traveling wave parametric amplifier device, a third order intermodulation product, or a fifth order intermodulation product.

21. A device, comprising:
a first dispersion resonator coupled to a first unit cell of a Josephson traveling wave parametric amplifier device and configured to receive a single pump tone to cause sideband suppression; and
a second dispersion resonator coupled to a second unit cell of the Josephson traveling wave parametric amplifier device and configured to receive the single pump tone to amplify a quantum signal.

22. The device of claim 21, wherein at least one of the first unit cell or the second unit cell comprises at least one Josephson junction and a shunt capacitor, and wherein at least one of the first dispersion resonator or the second dispersion resonator is selected from a group consisting of a lumped element resonator and a transmission line resonator.

23. The device of claim 21, wherein the second dispersion resonator reduces phase-mismatch to provide a defined four-wave mixing operation, and wherein the first dispersion resonator suppresses at least one of a third order harmonic of the single pump tone applied to the Josephson traveling wave parametric amplifier device, a third order intermodulation product, or a fifth order intermodulation product.

24. The device of claim 21, wherein the first dispersion resonator operates at a defined operating frequency to create a stopband that increases dispersion and attenuates at least one of a third order harmonic of the single pump tone applied to the Josephson traveling wave parametric amplifier device, a third order intermodulation product, or a fifth order intermodulation product, and wherein the first dispersion resonator operates at the defined operating frequency to improve at least one of: quantum efficiency, gain per unit length, stability, or noise performance of the Josephson traveling wave parametric amplifier device.

25. The device of claim 21, wherein phase-mismatch corresponding to a four-wave mixing generation of at least one of a third order harmonic of the single pump tone applied to the Josephson traveling wave parametric amplifier device, a third order intermodulation product, or a fifth order intermodulation product is maximized.
